(19) United States
(12) Patent Application Publication
(10) Pub. No.: US 2026/0166563 A1
(43) Pub. Date: Jun. 18, 2026

(54) LIQUID CHEMICAL SUPPLY SYSTEM HAVING MAGNETIC PARTICLE REMOVAL AND RELATED METHODS

(71) Applicant: Taiwan Semiconductor Manufacturing Company Limited, Hsin-Chu (TW)

(72) Inventors: Yu-Cing LI, Kaohsiung City (TW); Yu-Chih CHAN, Hsinchu County (TW); Lien-Fang WU, Hsinchu City (TW)

(21) Appl. No.: 18/985,238

(22) Filed: Dec. 18, 2024

(51) Int. Cl. B03C 1/28; H01L 21/02; H01L 21/306

(52) U.S. Cl. CPC B03C 1/288; B03C 2201/18; B03C 2201/22; H10P 50/642; H10P 70/20

(57) ABSTRACT

A method is provided. The method includes: flowing a liquid chemical through an opening defined in a body, the liquid chemical having magnetic particles dispersed therein; forming cleaned liquid chemical, including forming a magnetic field in the opening by a magnetic device mounted to the body; flowing the cleaned liquid chemical to a semiconductor processing tool; and performing a semiconductor process on a semiconductor wafer by the semiconductor processing tool by the cleaned liquid chemical.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic view of a system for supplying a material, in accordance with some embodiments.

FIG. 1B illustrates a detailed schematic view of the system, in accordance with some embodiments.

FIG. 2 illustrates a detailed schematic view of a transport line section of the system that has magnetic particle removal devices, in accordance with some embodiments.

FIG. 3A illustrates a schematic view of a magnetic particle removal device, in accordance with some embodiments.

FIG. 3B illustrates a schematic view of a magnetic particle removal device, in accordance with some embodiments.

FIG. 3C illustrates a schematic view of a magnetic particle removal device, in accordance with some embodiments.

FIG. 3D illustrates a schematic view of a magnetic particle removal device, in accordance with some embodiments.

FIG. 3E illustrates a schematic view of a magnetic particle removal device, in accordance with some embodiments.

FIG. 3F illustrates a schematic view of a magnetic particle removal device, in accordance with some embodiments.

FIG. 3G illustrates a schematic view of a magnetic particle removal device, in accordance with some embodiments.

FIG. 4 illustrates a schematic view of a centrifugal particle removal device, in accordance with some embodiments.

FIG. 5 illustrates a schematic view of a particle monitoring system, in accordance with some embodiments.

FIG. 6 is a flow diagram illustrating a method, in accordance with some embodiments.

FIG. 7 is a flow diagram illustrating a method, in accordance with some embodiments.

FIG. 8 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

With progress in advanced semiconductor process nodes, a production line can be affected by contamination events associated with supply of liquid chemical materials, such as isopropyl alcohol (IPA), developers, etchants, cleaners, and the like. In advanced processing, particle size detection resolution has reached 19 nanometers (nm) or lower. In many liquid supply systems, magnetic nanoparticles, such as including iron, nickel or the like, that are not removed from a liquid chemical can result in cone defects during semiconductor processing of an integrated circuit (IC) wafer.

Cone defects are a long-term problem in semiconductor manufacturing processes and related industries. Micro-pollutants, such as metal impurities, are present in the form of insoluble particles, which affects yield. For example, under high pH conditions, magnetic metal elements, such as Fe and Al, hydrolyze into hydroxides having very low solubility (e.g., Ksp is very small). Further, surfactants contain-O- ligands that can form complex compounds with the magnetic metal elements. Filters used for filtering nanoparticles struggle to filter smaller nanoparticles, such as those formed by magnetic metal elements as just described.

In embodiments of the disclosure, a liquid supply system includes one or more magnetic filtration devices that can be mounted to a pipeline, filter housing or the like. The magnetic filtration devices are beneficial to remove magnetic micro-or nano-pollutants (e.g., metal particles, etc.). Adsorption or polymerization amplification via strong magnets or electromagnets of the magnetic filtration devices removes magnetic metal particles (e.g., Fe, Ni, Al or the like). The magnetic filtration devices perform contactless removal of metal particles from alkalines, organic solvents, water, gases, and other fluids. As a result, micro-or nano-pollution is significantly reduced. For example, preliminary experimental results indicate that selection of stronger magnetic force of the magnet(s) and longer adsorption time can reduce count of metal particles in the liquid chemical by 30% or more, which can effectively reduce incidence of cone defects and increase yield.

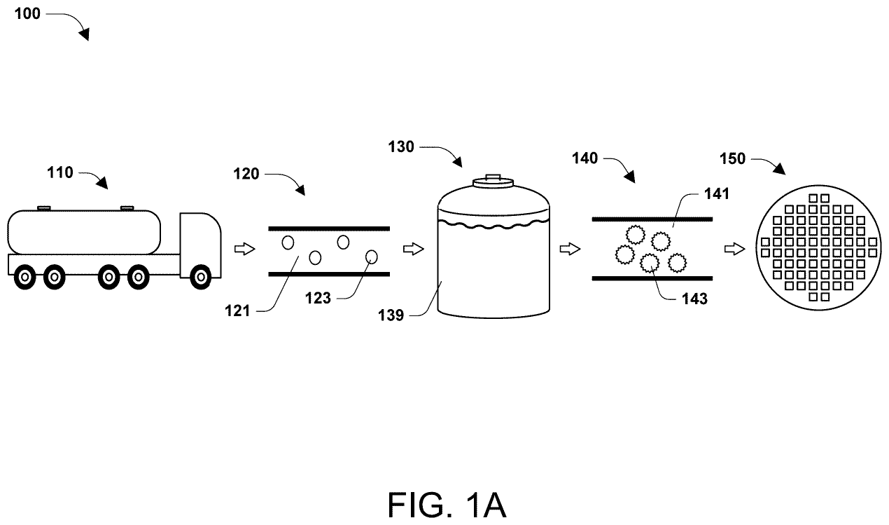

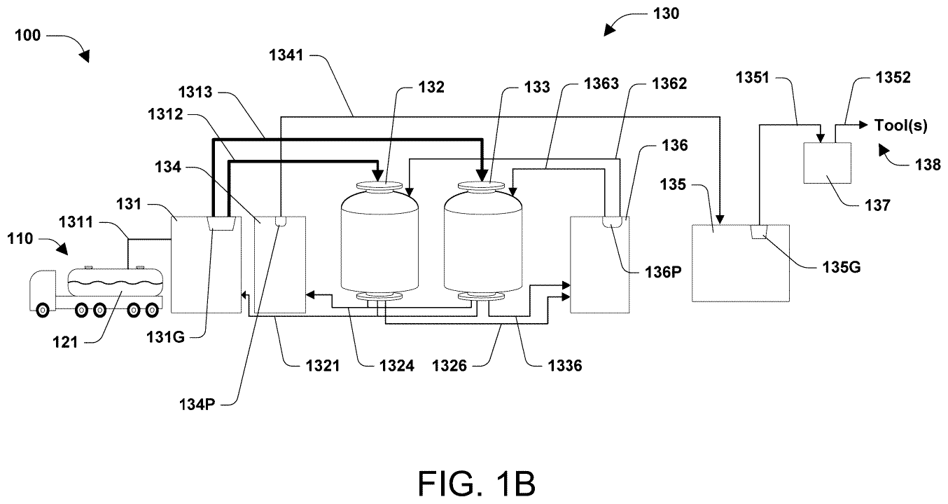

FIG. 1A illustrates a schematic view of a system 100 for supplying a material, in accordance with some embodiments. FIG. 1B illustrates a detailed schematic view of the system 100, in accordance with some embodiments.

In some embodiments, a liquid chemical 121 is transferred from a tanker truck 110 to a factory supply system 130 through a process that can include one or more of preparation, connection, pumping, and monitoring. In some embodiments, the liquid chemical 121 can include an alkaline, an organic solvent, water, isopropyl alcohol (IPA), an acid, and the like. In some embodiments, the liquid chemical 121 includes tetramethylammonium hydroxide (TMAH). The truck 110 can be positioned on a selected pad and grounded. Then, flexible hoses of a transport system 120 are connected between a discharge outlet(s) of the truck 110 and a tank of the factory supply system 130, and vapor recovery systems may optionally be used for volatile chemicals. A pump, either on the truck 110 or at the factory supply system 130, drives the liquid transfer, with flow controlled by valves and monitored by sensors to improve safe operation. Level of liquid chemical 121 in the factory supply system 130 can be monitored closely to prevent overfilling, and leak detection systems are optionally used. After the transfer, hoses can be drained, disconnected, and secured.

The factory supply system 130 can include one or more storage tanks, pumps, filtration systems, monitoring systems, quality measurement systems, and the like. Liquid chemical 141 can be supplied from the storage tanks to online tools, such as etchers or cleaners, through a system of pipelines and pumps selected to provide uniform flow and pressure. The liquid chemicals 141 and the liquid chemicals 121 can be the same as or different than each other. In some embodiments, the liquid chemicals 141 supplied to the tools are substantially the same as the liquid chemicals 121 received from the truck 110. For example, the liquid chemicals 121, 141 can both be IPA. In some embodiments, the liquid chemicals 141 are different in one or more aspects from the liquid chemicals 121. For example, additives may be mixed in with the liquid chemicals 121 in the factory supply system 130 to form the liquid chemicals 141. In another example, the liquid chemicals 121 in the factory supply system 130 may be “aged” to form the liquid chemicals 141 via a chemical reaction that is allowed to proceed for a selected time. Aging can be performed on etchants (e.g., acids) prior to supplying to the tools, for example.

The pumps draw the liquid chemical 141 from the storage tanks and transport it through compatible pipelines, with valves and flow meters controlling and monitoring the flow. The pumps can be calibrated for the selected chemical. An example pipeline 140 is depicted in FIG. 1A. The liquid chemical 141 may pass through a filter(s) to remove particles 123 prior to being supplied to the tools, where the liquid chemical 141 is introduced into process chambers. In some systems, excess liquid chemical 141 is collected for reuse or waste treatment, providing safe and precise delivery of the liquid chemical 141 to support the manufacturing process.

In some embodiments, the tools are operable to perform one or more semiconductor manufacturing process operations on a first semiconductor wafer 150. The first semiconductor wafer 150 (or simply “the wafer 150”) comprises at least one of a substrate, a photomask, a semiconductor device, a dielectric layer, an epitaxial layer, a silicon-on-insulator (SOI) structure, a semiconductor layer, a conductive material layer, a die, etc. The first semiconductor wafer 150 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The first semiconductor wafer 150 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the first semiconductor wafer 150 are within the scope of the present disclosure.

As depicted in FIG. 1A, the liquid chemical 121 supplied to the factory supply system 130 from the truck 110 has particles 123 dispersed therein. When the liquid chemical 121 is transferred from the truck 110 to the factory supply system 130, the liquid chemical 121 may contain the particles or “particulate contaminants” 123, such as residual particles from previous loads, including dust, rust, or chemical remnants if the truck 110 was not properly cleaned. Environmental contaminants, such as dust or dirt can enter during the transfer from the truck 110 to the factory supply system 130, for example, if connections are not fully sealed. Small particles from hoses, fittings, or pipelines, such as rubber fragments, metal shavings, or corrosion byproducts, may be introduced. Contaminants from a manufacturing process that forms the liquid chemical 121, including trace impurities or packaging debris, and chemical degradation products formed during storage, can also contribute to particulate contamination depicted by the particles 123.

Then, when the liquid chemical 141 is supplied to the tools via the pipeline(s) 140, particles 143 may be present in and dispersed throughout the liquid chemical 141. The particles 143 can include a portion of the particles 123 that are not filtered via the filtration system(s) prior to exiting the tank(s) of the factory supply system 130. The particles 143 can also include agglomerates of the particles 123 that form during storage in the tank(s) of the factory supply system 130. Other sources of the particles 143 can include one or more of pipeline debris, seal and/or gasket material, chemical precipitates, microbial contaminants, residual contaminants, and the like. The particles 143 being present in the liquid chemical 141 can result in process defects on the wafer 150, which reduce yield. For example, the particles 143 can be magnetic nanoparticles that result in cone defects on the wafer 150. In some embodiments, the particles 143 include nanoparticles that have size greater than about 20 nanometers (nm).

A particle monitoring or measuring system can determine concentration of particles 143 in the factory supply system 130. In response to the concentration of particles 143 exceeding a threshold value, various actions may be taken to mitigate the reduction in yield that is associated with exceeding the threshold value. For example, one or more transport lines, filtration systems, pumps or the like may be taken offline for maintenance, one or more flushing operations may be performed to remove particles 143 from transport lines, filtration systems, pumps, and the like. In another example, a system-wide preventative maintenance may be performed that removes particles 143 from the factory supply system 130.

FIG. 1B illustrates a detailed schematic view of the system 100, in accordance with some embodiments.

The system 100 includes the factory supply system or “liquid supply system” 130.

The liquid supply system 130 includes an intake assembly 131, a first storage tank or drum 132, an optional second storage tank or drum 133, a retrieval assembly 134, a supply assembly 135, a feedback assembly 136, and a valve manifold box (VMB) 137.

The intake assembly 131 is operable to receive the liquid chemical 121 from the truck 110 via a transport line 1311. The intake assembly 131 is further operable to output the liquid chemical 121 to the first storage tank 132, the second storage tank 133, or both. The intake assembly 131 is connected to the first storage tank 132 via a transport line 1312. The intake assembly 131 is connected to the second storage tank 133 via a transport line 1313. In some embodiments, the intake assembly 131 includes one or more valves that are coupled to the transport lines 1311, 1312, 1313 to control (e.g., enable or disable) flow of the liquid chemical 121 into and out of the intake assembly 131 via the transport lines 1311, 1312, 1313.

To supply the liquid chemical 121 to the first and second storage tanks 132, 133, the intake assembly 131 can include one or more pumps, one of which is depicted in FIG. 1B as a pump 131G. In some embodiments, the pump 131G includes a gas pressure pump, a pneumatic pump, a mechanical pump, or the like. The gas pressure pump can include one or more of a gas supply, an inlet, and the like, that generate a positive pressure differential that enables the liquid chemical 121 to be outputted from the intake assembly 131 without significant fluctuation in a flow rate thereof. The gas pressure pump can control pressure of a gas, such as N₂, He, Ar, CO₂, or the like that is supplied and held in the intake assembly 131. The mechanical pump can be or include one or more of piston pumps, plunger pumps, diaphragm pumps, gear pumps, lobe pumps, screw pumps, vane pumps, peristaltic pumps, centrifugal pumps, axial flow pumps, vacuum pumps, sump pumps, hydraulic pumps, and the like. In embodiments in which the pump 131G is the mechanical pump, the pump 131G is operable to generate variable pressure. As such, the pump 131G, which may include reciprocating or rotary mechanisms, produces pressure pulses in the flow of the liquid chemical 121.

In some embodiments, the intake assembly 131 includes a filter or filtration system. The intake assembly 131 can receive liquid chemical 121 from the first storage tank 132, the second storage tank 133, or both via a transport line 1321. Then, the filter or filtration assembly thereof can remove particles from the liquid chemical 121 before supplying the liquid chemical 121 after filtering to the first storage tank 132, the second storage tank 133, or both.

The retrieval assembly 134 and the supply assembly 135 operate to supply or deliver the liquid chemical 121 to one or more semiconductor processing tools 138, such as an etching tool, a cleaning tool, or the like. The retrieval assembly 134 is in fluid communication with the first and second storage tanks 132, 133 via a transport line 1324 to draw and/or receive the liquid chemical 121 from the first and second storage tanks 132, 133. In some embodiments, the retrieval assembly 134 includes a tank therein, in which the liquid chemical 121 can be stored temporarily or buffered prior to transport to the supply assembly 135 via a transport line 1341. The retrieval assembly 134 is in fluid communication with the supply assembly 135 via the transport line 1341. In some embodiments, the retrieval assembly 134 includes one or more pumps, a pump 134P of which is depicted in FIG. 1B. The pump 134P is a mechanical pump, such as one of the mechanical pumps described previously with reference to the pump 131G, in some embodiments. The pump 134P is operable to pump the liquid chemical 121 out of the retrieval assembly 134 to the supply assembly 135 via the transport line 1341.

The supply assembly 135 is operable to supply the liquid chemical 121 to one or more tools via a transport line 1351. The supply assembly 135 is in fluid communication with the VMB 137 and the retrieval assembly 134. In some embodiments, the supply assembly 135 includes a tank therein, in which the liquid chemical 121 can be stored temporarily or buffered prior to transport to the VMB 137. The supply assembly 135 is in fluid communication with the VMB 137 via the transport line 1351. In some embodiments, the supply assembly 135 includes one or more pumps, a pump 135G of which is depicted in FIG. 1B. The pump 135G is a gas pressure pump, such as similar to the gas pressure pump described previously with reference to the pump 131G, in some embodiments. The pump 135G is operable to pump the liquid chemical 121 out of the supply assembly 135 to the VMB 137 via a transport line 1351.

The VMB 137 includes one or more valves that are in fluid communication with a corresponding tool of the of one or more semiconductor processing tools 138. The valve(s) are in fluid communication with the corresponding tool(s) of the semiconductor processing tools 138 via one or more transport lines 1352. A single transport line 1352 is depicted in FIG. 1B. In some embodiments, number of the transport lines 1352 is equal to number of the semiconductor processing tools 138 that are supplied liquid chemical 121 by the VMB 137.

The feedback assembly 136 is operable to receive the liquid chemical 121 from the first and/or second storage tank 132, 133 via transport lines 1326, 1336, filter the received liquid chemical 121 and output the filtered liquid chemical 121 back to the first and/or second storage tank 132, 133 via transport lines 1362, 1363. The feedback assembly 136 is in fluid communication with the first and/or second storage tank 132, 133. For example, the feedback assembly 136 is in fluid communication with the first storage tank 132 via the transport line 1326 to receive the liquid chemical 121 from the first storage tank 132, and is in fluid communication with the first storage tank 132 via the transport line 1362 to output the liquid chemical 121 to the first storage tank 132. In some embodiments, the feedback assembly 136 includes one or more filters that are operable to remove particles from the liquid chemical 121 received by the feedback assembly 136 from the first and/or second storage tank 132, 133. The feedback assembly 136 includes one or more pumps, a pump 136P of which is operable to output the liquid chemical 121 to the first and/or second storage tank 132, 133. The pump 136P is a mechanical pump, such as one of the mechanical pumps described previously with reference to the pump 131G, in some embodiments.

One or more of the transport lines 1311, 1312, 1313, 1321, 1324, 1326, 1336, 1341, 1351, 1352, 1362, 1363 can be or include a single transport line or two or more transport lines arranged in parallel, for example, which can be beneficial to provide redundancy. Namely, a first transport line of the two or more transport lines can conduct the liquid chemical 121 while a second transport line of the two or more transport lines is shut off. While the second transport line is shut off, the second transport line may be cleaned or undergo other preventative maintenance, repair, or replacement. Each of the transport lines 1311, 1312, 1313, 1321, 1324, 1326, 1336, 1341, 1351, 1352, 1362, 1363 can include one or more transport line segments, one or more drains, one or more filter assemblies. Each of the transport lines 1311, 1312, 1313, 1321, 1324, 1326, 1336, 1341, 1351, 1352, 1362, 1363 can include one or more magnetic filtration devices, one or more centrifugal filtration devices, or both.

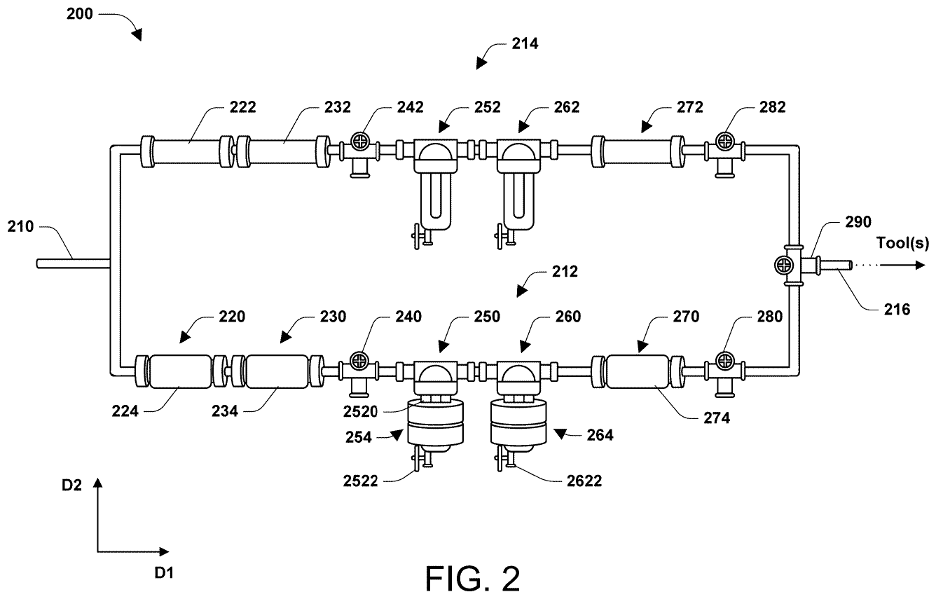

FIG. 2 illustrates a detailed schematic view of a transport line 200, in accordance with some embodiments. The transport line 200 can be an embodiment of one or more of the transport lines 1311, 1312, 1313, 1321, 1324, 1326, 1336, 1341, 1351, 1352, 1362, 1363 of FIG. 1B and can be included in the system 100 described with reference to FIGS. 1A and 1B. It should be understood that the transport line 200 can be included in liquid supply systems other than the system 100 described with reference to FIGS. 1A and 1B.

The transport line 200 includes an inlet 210, an outlet 216, a first line 212, a second line 214, and an optional selection device 290. The first and second lines 212, 214 extend from the inlet 210 to the outlet 216. In some embodiments, the selection device 290 is connected between the first line 212, the second line 214, and the outlet 216. The selection device 290 is operable to select one of the first line 212 or the second line 214 to conduct liquid chemical (e.g., the liquid chemical 121) to the outlet 216 and block the other of the first line 212 and the second line 214 from conducting the liquid chemical to the outlet 216. In some embodiments, an additional selection device 290 is connected between the first line 212, the second line 214, and the inlet 210. As such, the first line 212 or the second line 214 can be drained of the liquid chemical and preventative maintenance may be performed thereon while the other of the first and second lines 212, 214 can conduct the liquid chemical to tools, which is beneficial to provide continuous supply of the liquid chemical to the tools.

The first line 212 includes one or more transport line segments, which can include a first transport line segment 220, a second transport line segment 230 and a third transport line segment 270. The first line 212 includes one or more filter assemblies, which can include a first filter assembly 250 and a second filter assembly 260. The first line 212 includes one or more drains, which can include a first drain 240 and a second drain 280.

In the first line 212, the second drain 280 is adjacent and in fluid communication with the selection device 290 and the third transport line segment 270, which is adjacent and in fluid communication with the second filter assembly 260, which is adjacent and in fluid communication with the first filter assembly 250, which is adjacent and in fluid communication with the first drain 240, which is adjacent and in fluid communication with the second transport line segment 230, which is adjacent and in fluid communication with the first transport line segment 220, which is adjacent and in fluid communication with the inlet 210.

In some embodiments, the second line 214 includes substantially the same or the same components and arrangement thereof as the first line 212. As depicted in FIG. 2, the second line 214 includes one or more transport line segments, which can include a fourth transport line segment 222, a fifth transport line segment 232 and a sixth transport line segment 272. The second line 214 includes one or more filter assemblies, which can include a third filter assembly 252 and a fourth filter assembly 262. The second line 214 includes one or more drains, which can include a third drain 242 and a fourth drain 282.

In the second line 214, the fourth drain 282 is adjacent and in fluid communication with the selection device 290 and the sixth transport line segment 272, which is adjacent and in fluid communication with the fourth filter assembly 262, which is adjacent and in fluid communication with the third filter assembly 252, which is adjacent and in fluid communication with the third drain 244, which is adjacent and in fluid communication with the fifth transport line segment 232, which is adjacent and in fluid communication with the fourth transport line segment 222, which is adjacent and in fluid communication with the inlet 210.

Each of the first, second, third, fourth, fifth and sixth transport line segments 220, 230, 270, 222, 232, 272 may be or include a tube segment that can have a magnetic filtration device (or “magnetic filter device” or “magnetic particle removal device”) attached or mounted thereto. The tube segments may each have an inner wall that defines a space through which liquid chemical may flow and an outer wall on which the magnetic filtration device can be mounted. Each of the tube segments may be or include a material that is inert to the liquid chemical that flows therethrough, such as perfluoroalkoxy alkane (PFA), polytetrafluoroethylene (PTFE), polyvinylidene fluoride (PVDF), polypropylene (PP), polyvinyl chloride (PVC), stainless steel, or the like.

Each of the first, second, third and fourth filter assemblies 250, 260, 252, 262 may include a housing having a filter element positioned therein. The filter element may contain a microporous membrane or the like. A housing 2520 of the first filter assembly 250 is labeled in FIG. 2. Other housings of the second, third and fourth filter assemblies 260, 252, 262 are not separately labeled for simplicity of illustration. The housing may define an inlet and an outlet. The liquid chemical may enter the housing via the inlet and have particles removed therefrom by the filter element to form filtered liquid chemical. Then, the filtered liquid chemical may exit the housing via the outlet. The housing may have an inner wall that defines a space through which liquid chemical may flow and an outer wall on which the magnetic filtration device can be mounted. Each of the first, second, third and fourth filter assemblies 250, 260, 252, 262 may include a drain. A first drain 2522 of the first filter assembly 250 and a second drain 2622 of the second filter assembly 260 are labeled in FIG. 2. Other drains of the third and fourth filter assemblies 252, 262 are not separately labeled for simplicity of illustration. The first drain 2522 is in fluid communication with the housing 2520 and is operable to drain liquid chemical from the first filter assembly 250. The second drain 2622 is in fluid communication with the housing 2620 and is operable to drain liquid chemical from the second filter assembly 260. Other drains of the third and fourth filter assemblies 252, 262 are similarly operable to remove liquid chemical from the respective one of the third and fourth filter assemblies 252, 262.

Each of the first, second, third and fourth drains 240, 280, 242, 282 (or “drains 240, 280, 242, 282”) may be or include a gravity-fed drain that is operable to drain the liquid chemical from the respective first or second line 212, 214. In some embodiments, each of the drains 240, 280, 242, 282 can include a drain body, a drain valve, an outlet, and an optional support. The drain body may be a cylindrical or pipe-shaped component, and may be include a corrosion-resistant material, such as stainless steel or PVC. The drain valve can be or include a gate, a plug, a ball valve or the like that is installed at the bottom of the drain body to control flow of the liquid chemical. The outlet can be a pipe or fitting connected to the bottom of the drain body that leads to a waste collection point, a treatment system or the like. The support can be or include a bracket or flange attached to the drain body to provide stability and secure the drain to the main liquid supply line (e.g., the second transport line segment 230). In operation, the liquid chemical can flow through the drain when the valve is closed. At a selected time, a portion or all of the liquid chemical may be drained for maintenance, cleaning, or emergency situations. To drain the liquid chemical, the drain valve is opened, allowing the liquid chemical to flow downward due to gravity. The liquid chemical flows through the outlet pipe and into the selected waste collection or treatment area. Once a selected amount of liquid chemical has been drained, the valve is closed to prevent further leakage.

As described with reference to FIGS. 1A and 1B, the liquid chemical passing through the transport line 200 may include magnetic microscale particles (or “microparticles”) or nanoscale particles (or “nanoparticles”), which can include Fe, Al, Ni, or the like. In some conditions, such as high pH environments, the nanoparticles can hydrolyze into hydroxides that have low solubility (Ksp). The nanoparticles can also form complex compounds, for example, due to interfacial activity of surfactants that contain-O- ligands. It is beneficial to increase size of the magnetic hydroxides or complex compounds via growth and/or aggregation. The inventors have found that generating a magnetic field in the interior of the first, second, third, fourth, fifth and sixth transport line segments 220, 230, 270, 222, 232, 272, the first, second, third and fourth filter assemblies 250, 260, 252, 262, or both can improve growth and/or aggregation of the magnetic hydroxides and/or complex compounds, and can promote adhesion of the magnetic hydroxides and/or complex compounds to interior walls of the first, second, third, fourth, fifth and sixth transport line segments 220, 230, 270, 222, 232, 272, the first, second, third and fourth filter assemblies 250, 260, 252, 262, or both.

In FIG. 2, magnetic particle removal devices or “magnetic devices” 224, 234, 274, 254, 264 are attached or mounted to the first, second and third transport line segments 220, 230, 270 and the first and second filter assemblies 250, 260, respectively. A first magnetic device 224 is positioned on the first transport line segment 220. A second magnetic device 234 is positioned on the second transport line segment 230. A third magnetic device 274 is positioned on the third transport line segment 270. At least one fourth magnetic device 254 is positioned on the first filter assembly 250. At least one fifth magnetic device 264 is positioned on the second filter assembly 260. Although depicted in FIG. 2 as single, continuous or monolithic magnetic devices, the first, second and third magnetic devices 224, 234, 274 can include two or more magnetic devices that are positioned adjacent each other, such as side-by-side.

The first, second and third magnetic devices 224, 234, 274 can extend along length of the first, second and third transport line segments 220, 230, 270, such as along a first direction D1 depicted in FIG. 2. In some embodiments, first length of the first, second and third magnetic devices 224, 234, 274 along the first direction D1 is about the same as second length of first, second and third transport line segments 220, 230, 270 along the first direction D1. In some embodiments, the first length is at least about 90% of the second length, at least about 80% of the second length, at least about 70% of the second length, at least about 60% of the second length, or another suitable value. The first, second, third and fourth filter assemblies 250, 260, 252, 262 can have first height that extends along a second direction D2 transverse (e.g., perpendicular to) the first direction D1. The fourth and fifth magnetic devices 254, 264 have second height that extends along the second direction D2. In some embodiments, the second height is at least about 20% of the first height, at least about 30% of the first height, at least about 40% of the first height, at least about 50% of the first height, or another suitable value.

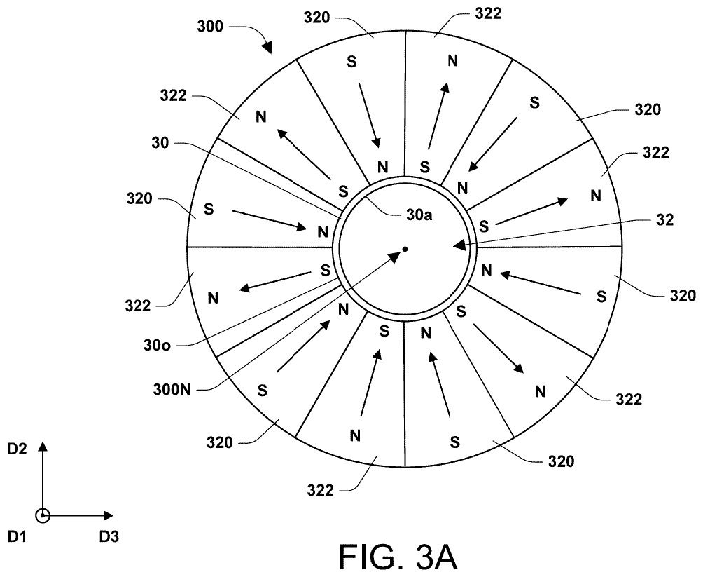

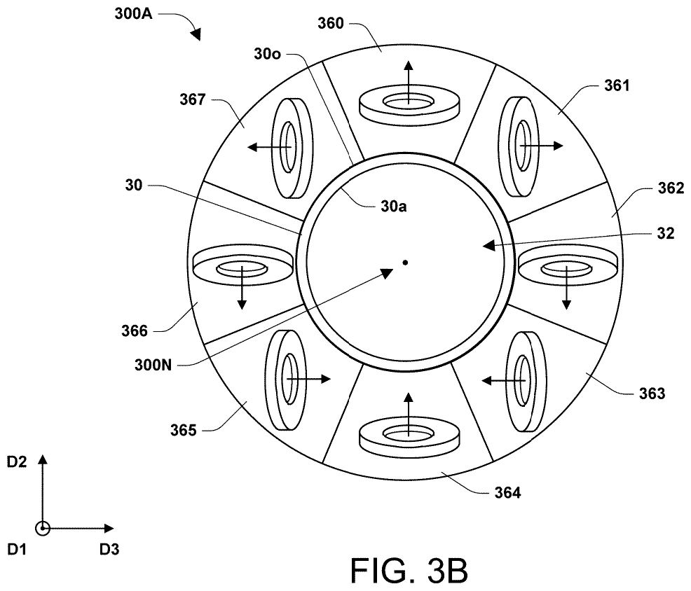

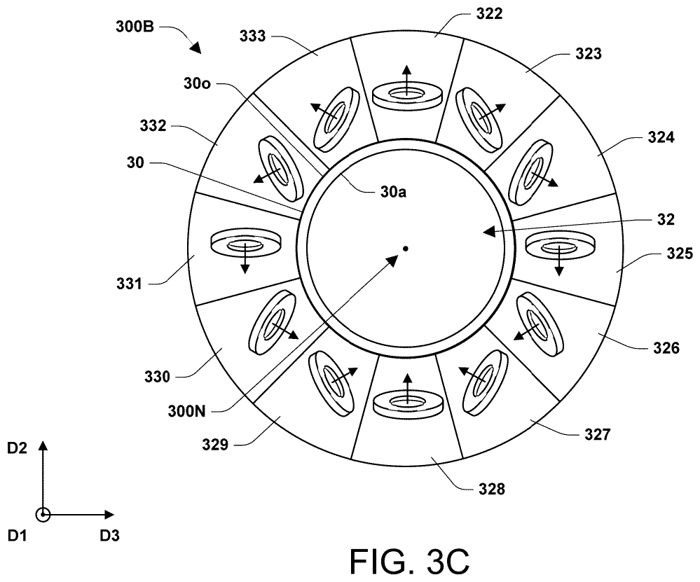

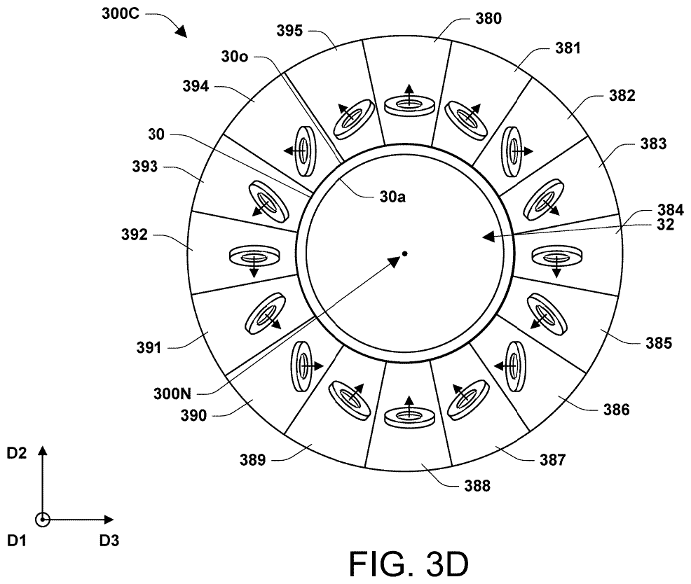

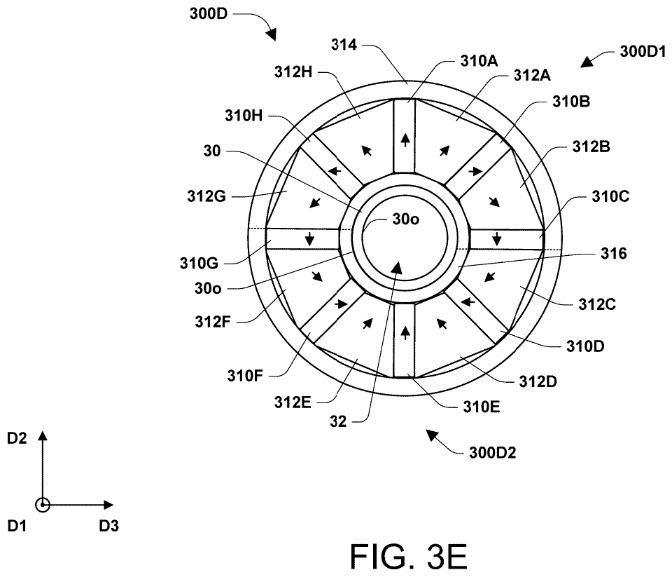

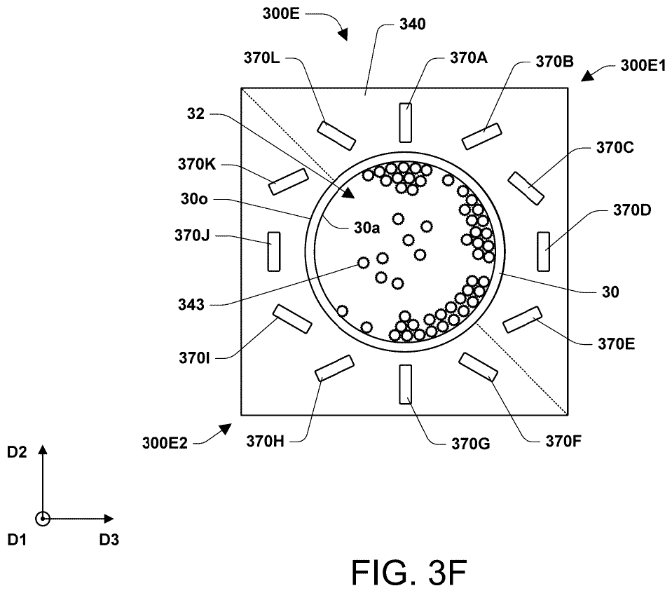

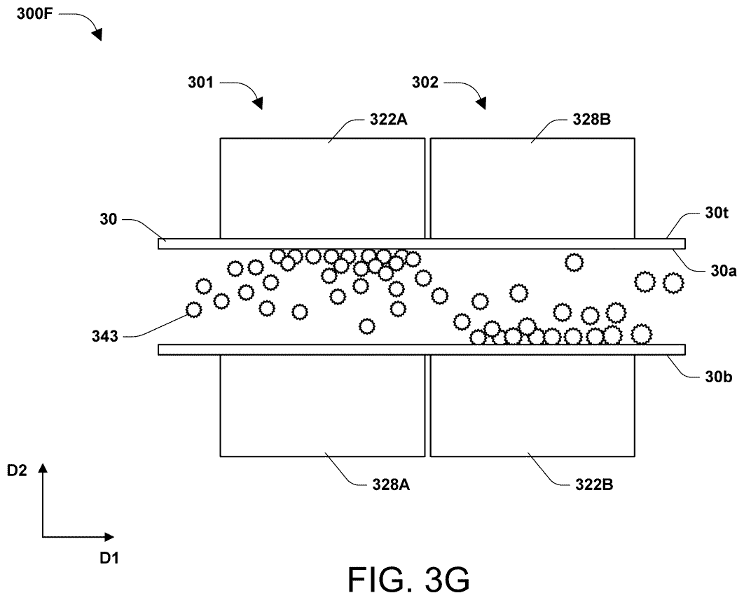

Each of the magnetic devices 224, 234, 274, 254, 264 may include magnets that are arranged as a radial magnet array or alternating pole circular magnet array. In some embodiments, the magnets are arranged as a Halbach array, which is beneficial to focus the magnetic field on one side (e.g., inside a tube segment or filter assembly) while canceling the magnetic field on the other side (e.g., outside the tube segment or filter assembly). Embodiments of magnetic devices 300, 300A, 300B, 300C, 300D, 300E, 300F are described with reference to FIGS. 3A-3H. Each of the magnetic devices 300, 300A, 300B, 300C, 300D, 300E, 300F may be an embodiment of the magnetic devices 224, 234, 274, 254, 264.

Each of the magnetic devices 224, 234, 274, 254, 264 is operable to be mounted or attached to the first line 212 or the second line 214 and to be removed from the first line 212 or the second line 214, for example, by a human operator or a robot arm. In some embodiments, in operation, during the magnetic devices 224, 234, 274, 254, 264 being mounted to the first line 212, the second line 214 is cleaned, maintained, or repaired. While the magnetic devices 224, 234, 274, 254, 264 are attached to the first line 212, magnetic particles flowing through the first line 212 are increased in size (e.g., by aggregation), adhered to one or more inner walls of the first line 212, or both. Then, the magnetic devices 224, 234, 274, 254, 264 may be removed from the first line 212. Removal of the magnetic devices 224, 234, 274, 254, 264 can be in response to a selected interval of time passing (e.g., a selected number of hours, days, weeks or the like) or in response to a particle count associated with the magnetic particles exceeding a threshold value. The magnetic devices 224, 234, 274, 254, 264 may then be attached to the second line 214. During the magnetic devices 224, 234, 274, 254, 264 being attached to the second line 214, the first line 212 may be cleaned, maintained, or repaired.

Cleaning of the first line 212, for example, can include opening the first and second drains 240, 280 and flushing the first line 212 by flowing the liquid chemical through the first line 212, which can remove the magnetic particles adhered to the inner walls of the first line 212. Following cleaning being completed, the first and second drains 240, 280 can be closed. Cleaning of the second line 214 is similar in most respects to that of the first line 212 and is not described again for brevity.

FIGS. 3A-3H illustrate schematic views of magnetic particle removal devices or “magnetic devices” 300, 300A, 300B, 300C, 300D, 300E, 300F, in accordance with some embodiments.

FIG. 3A illustrates a schematic view of a magnetic particle removal device or “magnetic device” 300, in accordance with some embodiments. The magnetic particle removal device 300 can be an embodiment of any of the magnetic devices 224, 234, 274, 254, 264 described with reference to FIG. 2.

The magnetic device 300 is mounted, attached, or fastened to a body 30. The body 30 can be an embodiment of the first, second, third, fourth, fifth and sixth transport line segments 220, 230, 270, 222, 232, 272, the first, second, third and fourth filter assemblies 250, 260, 252, 262, or the like. Liquid chemical, such as the liquid chemical 121, can flow through an opening 32 defined by the body 30 along the first direction D1 that is transverse the second direction D2 and a third direction D3 depicted in FIG. 3A. The body 30 has an inner wall 30a and an outer wall 30o. The outer wall 30o faces the magnetic device 300 and the inner wall 30a faces the opening 32.

The magnetic device 300 depicted in FIG. 3A includes first magnets 320 and second magnets 322 that are arranged alternately around the body 30 and may wrap around the body 30. For example, each first magnet 320 may be immediately adjacent two second magnets 322 on either side thereof, and each second magnet 322 may be immediately adjacent two first magnets 320 on either side thereof. The first magnets 320 have wedge shape in which a north pole thereof is proximal the body 30 and a south pole thereof is distal the body 30. The second magnets 322 have wedge shape in which a south pole thereof is proximal the body 30 and a north pole thereof is distal the body 30. Each of the first and second magnets 320, 322 can extend along the first direction D1. In some embodiments, each of the first and second magnets 320, 322 has the same or substantially the same shape (e.g., length, height, arc length, angle, etc.). In some embodiments, one or more of the first and second magnets 320, 322 has shape that differs from others of the first and second magnets 320, 322. For example, the first magnets 320 may have arc length that exceeds arc length of the second magnets 322. Each of the first and second magnets 320, 322 may be or include the same material(s) and may thus have the same or substantially the same magnetism (other than reversal of poles). For example, each of the first and second magnets 320, 322 may be a strong magnet that includes one or more of neodymium iron boron (NdFeB), samarium cobalt (SmCo), ferrite (Ceramic), alnico (Aluminum, Nickel, Cobalt), iron, steel, an alloy, a bonded magnetic material (e.g., NdFeB or ferrite powder mixed with a polymer binder), combinations thereof or the like.

The wedge shape of the first and second magnets 320, 322 can include curved inner and outer walls having substantially straight sidewalls that are tapered and extend therebetween. The inner walls are immediately adjacent or in direct contact with the outer wall 30o of the body 30. In some embodiments, curvature of the inner walls is substantially the same as curvature of the outer wall 30o. In some embodiments, ratio of the inner walls that is in direct contact with the outer wall 30o exceeds about 60%, about 70%, about 80%, about 90%, about 95% or another suitable value.

In some embodiments, the first and/or second magnets 320, 322 can include electromagnets. For example, the electromagnets can include a toroidal core including a magnetic material (e.g., soft iron or steel, ferrites, laminated silicon steel, etc.), with a coil of wire (e.g., copper, aluminum, etc.) wrapped around the core to generate the magnetic field when current flows through the wire. The electromagnets may be mounted in a housing that is an insulator, which is beneficial to electrically isolate the electromagnets from each other.

The arrangement of the first and second magnets 320, 322 described with reference to FIG. 3A is beneficial to aggregate or enlarge the magnetic particles and attract the magnetic particles to an inner wall 30a of the body 30, to which the magnetic particles may adhere.

In operation, the magnetic device 300 can generate a magnetic field in an opening 32 defined by the inner wall 30a of the body 30. The liquid chemical can traverse through the opening 32. Behavior of magnetic particles of the liquid chemical in a central region (e.g., in the opening 32) of the magnet array of the magnetic device 300, where multiple magnetic poles converge, can be complex due to interaction of magnetic fields from the first and second magnets 320, 322 that wrap around the opening 32.

In the opening 32, the magnetic fields from the surrounding first and second magnets 320, 322 overlap. Each of the first and second magnets 320, 322 contributes a portion of its magnetic field, and a resulting magnetic field is a vector sum of the magnetic fields from the first and second magnets 320, 322. Because the first and second magnets 320, 322 are arranged in a circular pattern with alternating north (N) and south(S) poles, contributions from each pole partially cancel each other out, which is more prevalent when the poles are equidistant from the center, as depicted in FIG. 3A. The magnetic field in the opening 32 may have some degree of symmetry about the center 300N of the magnetic device 300, but characteristics of the field can vary due to variations in geometry and strength of the individual first and second magnets 320, 322. At the very center 300N, if all of the first and second magnets 320, 322 are substantially identical and substantially aligned, contributions from each of the first and second magnets 320, 322 can cancel out, resulting in a region of low magnetic flux density.

In an ideal situation, where the first and second magnets 320, 322 are perfectly symmetrically arranged with alternating poles, the magnetic field at the very center 300N can approach zero. This is because the magnetic fields from adjacent north and south poles are equal in magnitude but opposite in direction, leading to near-perfect cancellation. This creates a null point in the magnetic field where the magnetic particles experience very little magnetic force. In this case, magnetic particles transversing exactly the center 300N may not experience a strong attractive force in any direction. Instead, the magnetic particles may tend to remain relatively still or may align randomly, depending on very small local field perturbations or imperfections in the symmetry.

Although the center 300N may be a null point or substantially null point, the magnetic field begins to increase in magnitude with increased distance from the center 300N toward the inner wall 30a, where the poles of the first and second magnets 320, 322 are located. This means that the magnetic field around the center 300N has a radial gradient, with the magnetic field strength increasing with proximity to the first and second magnets 320, 322.

Due to the magnetic gradient, magnetic particles that are near the center 300N but not exactly at the null point are pulled outward toward regions of higher magnetic field strength, such as the inner wall 30a. This is because ferromagnetic materials, like iron, tend to be attracted to areas of higher magnetic flux density. As the magnetic particles are attracted outward from the center 300N, the magnetic particles can align with local magnetic field lines, forming a radial pattern pointing away from the center 300N.

In a region in close proximity to the center 300N or “a central region,” where multiple magnetic fields overlap, complex interference patterns may be present, particularly where the magnetic fields are not perfectly symmetrical. Small variations in magnet placement or strength can result in regions of constructive or destructive interference, which can result in areas of slightly stronger or weaker magnetic fields even within the central region. In regions where the magnetic field is slightly stronger (e.g., due to constructive interference), the magnetic particles may align more strongly. In areas of weaker magnetic field, the magnetic particles may show less alignment or even random orientation. Generally, the overall effect of the magnetic device 300 is a tendency for the magnetic particles to move outward toward the inner wall 30a, but some local variations in alignment may result from the aforementioned interference effects.

Dynamic behavior may be present due to turbulence of the liquid chemical as it passes through the body 30. Although the array of first and second magnets 320, 322 may be stationary, relative to the magnetic particles swept along by the turbulent liquid chemical, the magnetic field experienced by the magnetic particles at the central region changes, such that behavior of the magnetic particles becomes dynamic. The magnetic particles may continuously adjust orientation and position based on the experienced changing field, particularly in the central region where small changes in the field can have noticeable effects due to lower overall field strength.

Generally, the exact center 300N of the array of first and second magnets 320, 322 can be a null point with little or no magnetic field due to symmetrical cancellation of the magnetic fields from the surrounding first and second magnets 320, 322. Moving away from the center 300N, the magnetic field strength increases, generating a radial gradient. Magnetic particles near the center 300N are weakly attracted to the center 300N but more strongly pulled outward toward the inner wall 30a, where the field strength is higher. Local variations in the magnetic field due to interference can cause slight deviations in alignment and motion of the magnetic particles, especially near the center 300N. In the central region, behavior of the magnetic particles can be relatively complex, but they generally experience weaker forces near the center 300N, with a tendency to align radially and move toward the inner wall 30a where the magnetic field strength is higher. Motion of the magnetic particles along the length of the body and turbulence in the liquid chemical can result in dynamic effects that tend to result in most of the magnetic particles being drawn to the inner wall 30a.

FIG. 3B illustrates a schematic view of the magnetic particle removal device or “magnetic device” 300A, in accordance with some embodiments.

In FIG. 3B, the magnetic device 300A includes eight magnets 360, 361, 362, 363, 364, 365, 366, 367 that are arranged in a Halbach array. Each of the magnets 360, 361, 362, 363, 364, 365, 366, 367 has magnetic field that is offset from that of an immediately adjacent magnet by substantially 90°. For example, a first magnet 360 has first magnetic field that is oriented along the second direction D2. A second magnet 361 immediately adjacent the first magnet 360 has second magnetic field that is offset from that of the first magnet 360 by 90°and is oriented along the third direction D3. A third magnet 362 immediately adjacent the second magnet 361 has third magnetic field that is offset from that of the second magnet 361 by 90°and that of the first magnet 360 by 180° and is oriented along the second direction D2 but opposite that of the first magnet 360. A fourth magnet 363 immediately adjacent the third magnet 361 has fourth magnetic field that is offset from that of the third magnet 362 by 90° and that of the second magnet 361 by 180° and is oriented along the third direction D3 but opposite that of the second magnet 361. The same arrangement continues for fifth, sixth, seventh and eighth magnets 364, 365, 366, 367 of the magnetic device 300A. Generally, each magnet of the magnets 360, 361, 362, 363, 364, 365, 366, 367 has magnetic field that is oriented substantially perpendicular to magnetic fields of immediately adjacent magnets on either side thereof. Each of the magnets 360, 361, 362, 363, 364, 365, 366, 367 has magnetic field that has substantially the same orientation of that of a magnet opposite thereto in the array. For example, the first magnet 360 and the fifth magnet 364 have magnetic fields that have substantially the same orientation (e.g., upward along the second direction D2).

In some embodiments, the magnets 360, 361, 362, 363, 364, 365, 366, 367 are wedge magnets as described with reference to FIG. 3A. In some embodiments, the magnets 360, 361, 362, 363, 364, 365, 366, 367 have a different shape, such as cubes, rectangular prisms, or the like. In some embodiments, the magnets 360, 361, 362, 363, 364, 365, 366, 367 are electromagnets. For example, the electromagnets can include a toroidal core including a magnetic material (e.g., soft iron or steel, ferrites, laminated silicon steel, etc.), with a coil of wire (e.g., copper, aluminum, etc.) wrapped around the core to generate the magnetic field when current flows through the wire. The electromagnets may be mounted in a housing that is an insulator, which is beneficial to electrically isolate the electromagnets from each other.

The wedge shape of the magnets 360, 361, 362, 363, 364, 365, 366, 367 can include curved inner and outer walls having substantially straight sidewalls that are tapered and extend therebetween. The inner walls are immediately adjacent or in direct contact with the outer wall 30o of the body 30. In some embodiments, curvature of the inner walls is substantially the same as curvature of the outer wall 30o. In some embodiments, ratio of the inner walls that is in direct contact with the outer wall 30 o exceeds about 60%, about 70%, about 80%, about 90%, about 95% or another suitable value.

In the opening 32, magnetic field generated by the magnetic device 300A may be generally unidirectional, such as in the positive second direction D2 (e.g., from the fifth magnet 364 toward the first magnet 360). The unidirectional magnetic field can be due to number of turns in the magnetic device 300A being two. Magnetic particles flowing though the opening 32 may aggregate or expand, and may move in the direction of the magnetic field in the opening 32 toward the inner wall 30a, such as toward the magnets 367, 360, 361. As a result, adherence of the magnetic particles to the inner wall 30a adjacent the magnets 367, 360, 361 is increased, which is beneficial to reduce concentration of the magnetic particles in the liquid chemical and prevent the magnetic particles from depositing on the wafer being processed using the liquid chemical.

FIG. 3C illustrates a schematic view of a magnetic particle removal device or “magnetic device” 300B, in accordance with some embodiments. The magnetic device 300B of FIG. 3C is similar in most respects to the magnetic device 300A of FIG. 3B.

In FIG. 3C, the magnetic device 300B includes twelve magnets 322, 323, 324, 325, 326, 327, 328, 329, 330, 331, 332, 333 that are arranged in a Halbach array. Each of the magnets 322, 323, 324, 325, 326, 327, 328, 329, 330, 331, 332, 333 has magnetic field that is offset from that of an immediately adjacent magnet by substantially 60°. For example, a first magnet 322 has first magnetic field that is oriented along the second direction D2. A second magnet 323 immediately adjacent the first magnet 322 has second magnetic field that is offset from that of the first magnet 322 by 60°(e.g., makes a +30° angle with the third direction D3). A third magnet 324 immediately adjacent the second magnet 323 has third magnetic field that is offset from that of the second magnet 323 by 60° and that of the first magnet 322 by 120° (e.g., makes a −30° angle with the third direction D3). A fourth magnet 325 immediately adjacent the third magnet 324 has fourth magnetic field that is offset from that of the third magnet 324 by 60° and that of the first magnet 322 by 180° and is oriented along the third direction D3 but opposite that of the first magnet 322. The same arrangement continues for fifth, sixth, seventh, eighth, ninth, tenth, eleventh, and twelfth magnets 326, 327, 328, 329, 330, 331, 332, 333 of the magnetic device 300.

Each of the twelve magnets 322, 323, 324, 325, 326, 327, 328, 329, 330, 331, 332, 333 can include the wedge shape. The wedge shape of the magnets 322, 323, 324, 325, 326, 327, 328, 329, 330, 331, 332, 333 can include curved inner and outer walls having substantially straight sidewalls that are tapered and extend therebetween. The inner walls are immediately adjacent or in direct contact with the outer wall 30o of the body 30. In some embodiments, curvature of the inner walls is substantially the same as curvature of the outer wall 30o. In some embodiments, ratio of the inner walls that is in direct contact with the outer wall 30o exceeds about 60%, about 70%, about 80%, about 90%, about 95% or another suitable value.

Similar to the magnetic device 300A described with reference to FIG. 3B, in the opening 32, magnetic field generated by the magnetic device 300B of FIG. 3C may be generally unidirectional, such as in the positive second direction D2 (e.g., from the seventh magnet 328 toward the first magnet 322). The unidirectional magnetic field can be due to number of turns in the magnetic device 300B being two. Generally, the magnetic devices 300A, 300B are similar in that both include the same number of turns, but number of magnets included the magnetic device 300B exceeds number of magnets included in the magnetic device 300A, and angular offset of the magnets of the magnetic device 300B is smaller than that of the magnets of the magnetic device 300A. Magnetic particles flowing though the opening 32 of FIG. 3C may aggregate or expand, and may move in the direction of the magnetic field in the opening 32 toward the inner wall 30a, such as toward the magnets 332, 333, 322, 323, 324. As a result, adherence of the magnetic particles to the inner wall 30a adjacent the magnets 332, 333, 322, 323, 324 is increased, which is beneficial to reduce concentration of the magnetic particles in the liquid chemical and prevent the magnetic particles from depositing on the wafer being processed using the liquid chemical.

FIG. 3D illustrates a schematic view of a magnetic particle removal device or “magnetic device” 300C, in accordance with some embodiments. The magnetic device 300C of FIG. 3D is similar in most respects to the magnetic devices 300A, 300B of FIGS. 3B, 3C.

In FIG. 3C, the magnetic device 300C includes sixteen magnets 380, 381, 382, 383, 384, 385, 386, 387, 388, 389, 390, 391, 392, 393, 394, 395 that are arranged in a Halbach array. Each of the magnets 380, 381, 382, 383, 384, 385, 386, 387, 388, 389, 390, 391, 392, 393, 394, 395 has magnetic field that is offset from that of an immediately adjacent magnet by substantially 45°. For example, a first magnet 380 has first magnetic field that is oriented along the second direction D2. A second magnet 381 immediately adjacent the first magnet 380 has second magnetic field that is offset from that of the first magnet 380 by 45° (e.g., makes a +45° angle with the third direction D3). A third magnet 382 immediately adjacent the second magnet 381 has third magnetic field that is offset from that of the second magnet 381 by 45° and that of the first magnet 380 by 90° (e.g., is oriented along the third direction D3). A fourth magnet 383 immediately adjacent the third magnet 382 has fourth magnetic field that is offset from that of the third magnet 382 by 45° and that of the first magnet 380 by 135° and makes a −45° angle with the third direction D3. The same arrangement continues for fifth, sixth, seventh, eighth, ninth, tenth, eleventh, twelfth, thirteenth, fourteenth, fifteenth, and sixteenth magnets 384, 385, 386, 387, 388, 389, 390, 391, 392, 393, 394, 395 of the magnetic device 300C.

Each of the sixteen magnets 380, 381, 382, 383, 384, 385, 386, 387, 388, 389, 390, 391, 392, 393, 394, 395 can include the wedge shape. The wedge shape of the magnets 380, 381, 382, 383, 384, 385, 386, 387, 388, 389, 390, 391, 392, 393, 394, 395 can include curved inner and outer walls having substantially straight sidewalls that are tapered and extend therebetween. The inner walls are immediately adjacent or in direct contact with the outer wall 30o of the body 30. In some embodiments, curvature of the inner walls is substantially the same as curvature of the outer wall 30o. In some embodiments, ratio of the inner walls that is in direct contact with the outer wall 30 o exceeds about 60%, about 70%, about 80%, about 90%, about 95% or another suitable value.

Similar to the magnetic devices 300A, 300B described with reference to FIGS. 3B, 3C, in the opening 32, magnetic field generated by the magnetic device 300C of FIG. 3D may be generally unidirectional, such as in the positive second direction D2 (e.g., from the ninth magnet 388 toward the first magnet 380). The unidirectional magnetic field can be due to number of turns in the magnetic device 300C being two. Generally, the magnetic devices 300A, 300B, 300C are similar in that all three include the same number of turns, but number of magnets included the magnetic device 300C exceeds number of magnets included in the magnetic devices 300A, 300B and angular offset of the magnets of the magnetic device 300C is smaller than that of the magnets of the magnetic devices 300A, 300B. Magnetic particles flowing though the opening 32 of FIG. 3D may aggregate or expand, and may move in the direction of the magnetic field in the opening 32 toward the inner wall 30a, such as toward the magnets 393, 394, 395, 380, 381, 382, 383. As a result, adherence of the magnetic particles to the inner wall 30a adjacent the magnets 393, 394, 395, 380, 381, 382, 383 is increased, which is beneficial to reduce concentration of the magnetic particles in the liquid chemical and prevent the magnetic particles from depositing on the wafer being processed using the liquid chemical.

FIG. 3E illustrates a schematic view of a magnetic particle removal device or “magnetic device” 300D, in accordance with some embodiments.

The magnetic device 300D is similar in some respects to the magnetic device 300C described with reference to FIG. 3D. For example, the magnetic device 300D includes two turns and sixteen magnets, which is similar to the magnetic device 300C. The sixteen magnets 310A, 312A, 310B, 312B, 310C, 312C, 310D, 312D, 310E, 312E, 310F, 312F, 310G, 312G, 310H, 312H include first magnets 310A, 310B, 310C, 310D, 310E, 310F, 310G, 310H and second magnets 312A, 312B, 312C, 312D, 312E, 312F, 312G, 312H that are arranged alternately in a ring or donut around the opening 32. Namely, each first magnet (e.g., the first magnet 310B) is immediately adjacent two second magnets (e.g., the second magnets 312A, 312B), and each second magnet (e.g., the second magnet 312A) is immediately adjacent two first magnets (e.g., the first magnets 310A, 310B).

The first magnets 310A, 310B, 310C, 310D, 310E, 310F, 310G, 310H have a first shape that is different than a second shape of the second magnets 312A, 312B, 312C, 312D, 312E, 312F, 312G, 312H. In some embodiments, the first shape is a bar shape that has rectangular profile in a plane formed by the second and third directions D2, D3. Height of the first shape exceeds width of the first shape. For example, the height of the first magnet 310A is along the second direction D2 and the width of the first magnet 310A is along the third direction D3. In another example, the height of the first magnet 310C is along the third direction D3 and the width of the first magnet 310C is along the second direction D2. Each of the first magnets 310A, 310B, 310C, 310D, 310E, 310F, 310G, 310H extends along the first direction D1, which is the same direction that the body 30 and the opening 32 therein extend along.

In some embodiments, the second shape of the second magnets 312A, 312B, 312C, 312D, 312E, 312F, 312G, 312H is a trapezoidal shape that has trapezoid profile in the plane formed by the second and third directions D2, D3. In some embodiments, the second shape has a first base and a second base. The first base is proximal the body 30 and the second base is distal the body 30. The second base has dimension that exceeds that of the first base. The second shape has tapered sidewalls that extends from the second base to the first base. In some embodiments, the tapered sidewalls are in direct contact with sidewalls of the first magnets 310A, 310B, 310C, 310D, 310E, 310F, 310G, 310H. Each of the second magnets 312A, 312B, 312C, 312D, 312E, 312F, 312G, 312H extends along the first direction D1, which is the same direction that the body 30 and the opening 32 therein extend along.

Magnetic fields of the first and second magnets 310A, 310B, 310C, 310D, 310E, 310F, 310G, 310H, 312A, 312B, 312C, 312D, 312E, 312F, 312G, 312H are arranged such that each successive magnet has magnetic field that is offset from magnetic field of the previous magnet by substantially 45°, which is similar to the arrangement described with reference to FIG. 3D. In such an arrangement, each successive first magnet 310A, 310B, 310C, 310D, 310E, 310F, 310G, 310H has magnetic field that is offset from magnetic field of the previous first magnet by 90°. Similarly, each successive second magnet 312A, 312B, 312C, 312D, 312E, 312F, 312G, 312H has magnetic field that is offset from magnetic field of the previous second magnet by substantially 90°.

In some embodiments, the magnetic device 300D includes an inner ring 316 and an outer ring 314. The magnets 310A, 310B, 310C, 310D, 310E, 310F, 310G, 310H, 312A, 312B, 312C, 312D, 312E, 312F, 312G, 312H are positioned between the inner ring 316 and the outer ring 314. The inner ring 316 is positioned between the magnets 310A, 310B, 310C, 310D, 310E, 310F, 310G, 310H, 312A, 312B, 312C, 312D, 312E, 312F, 312G, 312H and the body 30. In some embodiments, an inner wall of the inner ring 316 is in direct contact with an outer wall of the body 30. In some embodiments, an outer wall of the inner ring 316 is in direct contact with one or more of the magnets 310A, 310B, 310C, 310D, 310E, 310F, 310G, 310H, 312A, 312B, 312C, 312D, 312E, 312F, 312G, 312H. In some embodiments, an inner wall of the outer ring 314 is in direct contact with one or more of the magnets 310A, 310B, 310C, 310D, 310E, 310F, 310G, 310H, 312A, 312B, 312C, 312D, 312E, 312F, 312G, 312H.

In some embodiments, the inner ring 316 and the outer ring 314 are operable to open to mount and remove the magnetic device 300D from the body 30. For example, as depicted by dashed lines in FIG. 3E, the magnetic device 300D can be arranged in two halves 300D1, 300D2 that can be separated from each other and joined to each other. The separating and joining can be via a hinge (not separately illustrated), such that the two halves can be opened and closed in a clamshell manner.

In embodiments in which the inner ring 316 is in place, the magnets 310A, 310B, 310C, 310D, 310E, 310F, 310G, 310H, 312A, 312B, 312C, 312D, 312E, 312F, 312G, 312H are not in direct contact with the outer wall 30 o of the body, but are instead separated therefrom by the inner ring 316.

FIG. 3F illustrates a schematic view of a magnetic particle removal device or “magnetic device” 300E, in accordance with some embodiments.

The magnetic device 300E is similar in many respects to the magnetic device 300B described with reference to FIG. 3C. For example, the magnetic devices 300B, 300E each include twelve magnets that are arranged in a Halbach array having two turns. The magnetic device 300E includes magnets 370A, 370B, 370C, 370D, 370E, 370F, 370G, 370H, 370I, 370J, 370K, 370L. Moving around the body 30, each of the magnets 370A, 370B, 370C, 370D, 370E, 370F, 370G, 370H, 370I, 370J, 370K, 370L has magnetic field that has an angular offset from that of an immediately preceding magnet equal to about 60°.

As depicted in FIG. 3F, each of the magnets 370A, 370B, 370C, 370D, 370E, 370F, 370G, 370H, 370I, 370J, 370K, 370L can be a bar magnet having rectangular profile in a plane that is orthogonal to length of the body 30 in the first direction D1. For example, the plane is formed by the second and third directions D2, D3. In some embodiments, one or more of the magnets 370A, 370B, 370C, 370D, 370E, 370F, 370G, 370H, 370I, 370J, 370K, 370L can have profile that is different than others of the magnets 370A, 370B, 370C, 370D, 370E, 370F, 370G, 370H, 370I, 370J, 370K, 370L. For example, the magnet 370A can have the rectangular profile and the magnet 370B can have a square profile, a wedge profile, a circular profile, or the like that is different than the rectangular profile.

Each of the magnets 370A, 370B, 370C, 370D, 370E, 370F, 370G, 370H, 370I, 370J, 370K, 370L can be positioned in (e.g., embedded in) a housing 340. In some embodiments, the housing 340 can be or include an insulator, such as a plastic or polymer (e.g., polycarbonate, polyamide, polyethylene, polypropylene, acrylonitrile butadiene styrene, polyphenylene sulfide, etc.), an epoxy resin, a ceramic, a glass-filled composite, a thermosetting plastic, silicone, or the like. In some embodiments, the housing 340 may have thickness in the first direction D1 that is in a range of about 0.5 centimeters to about 50 centimeters. In some embodiments, the magnetic device 300E may include a first portion 300E1 and a second portion 300E2, which may be indicated by dashed lines in the housing 340. The magnetic device 300E is operable to open and close for mounting and removing the magnetic device 300E to and from the body 30. The housing 340 depicted in FIG. 3F has square profile in the plane orthogonal to the third direction D3. In some embodiments, the housing 340 has rectangular profile, circular profile, elliptical profile, non-rectangular polygonal profile (e.g., triangular, pentagonal, hexagonal, octagonal, etc.), or the like.

In operation, the magnetic device 300E can aggregate and attract magnetic particles 343 (e.g., iron, aluminum, nickel, etc.) in the opening 32. For example, as depicted in FIG. 3F, many of the magnetic particles 343 may migrate toward and adhere to the inner wall 30a of the body 30. The magnetic particles 343 depicted in FIG. 3F are not drawn to scale, and may be microparticles or nanoparticles that are not visible to the naked eye.

In embodiments including the housing 340, the magnets 370A, 370B, 370C, 370D, 370E, 370F, 370G, 370H, 370I, 370J, 370K, 370L that are embedded in the housing 340 may not be in direct contact with the outer wall 30o of the body 30. In some embodiments, the magnets 370A, 370B, 370C, 370D, 370E, 370F, 370G, 370H, 370I, 370J, 370K, 370L may be offset from the outer wall 30o by a distance that is in a range of about 0.5 cm to about 2 cm.

FIG. 3G illustrates a schematic view of a magnetic particle removal device or “magnetic device” 300F, in accordance with some embodiments.

The magnetic device 300F includes a first magnetic device 301 and a second magnetic device 302 that are mounted to the body 30. The first and second magnetic devices 301, 302 may each be one of the magnetic devices 300, 300A, 300B, 300C, 300D, 300E described with reference to FIGS. 3A-3F. The first and second magnetic devices 301, 302 may each be the same magnetic device (e.g., the magnetic device 300B) or may be different magnetic devices from each other. For example, the first magnetic device 301 may be or include the magnetic device 300B and the second magnetic device 302 may be or include the magnetic device 300D. The first magnetic device 301 and the second magnetic device 302 may have similar or different magnetic flux density. In some embodiments, each of the first magnetic device 301 and the second magnetic device 302 may have magnetic flux density that exceeds about 500 Gauss (G), about 1000G, about 2000G, about 3000G, about 4000G or another suitable value. Below about 500G, the magnetic flux density may be insufficient to aggregate and/or adhere the magnetic particles 343.

When the first and second magnetic devices 301, 302 each include the same magnetic device, respective orientations of the first and second magnetic devices 301, 302 may be the same as each other or different than each other. For example, as depicted in FIG. 3G, the first magnetic device 301 can include the magnetic device 300B oriented such that first and seventh magnets 322A (e.g., the first and seventh magnets 322, 327) thereof are on first and second sides 30t, 30b of the body 30 and the second magnetic device 302 can include the magnetic device 300B oriented such that first and seventh magnets 322B, 328B thereof (e.g., the first and seventh magnets 322, 327) thereof are on the second and first sides 30b, 30t of the body 30. As such, the first magnetic device 301 can have first magnetic field that is in a different direction that a second magnetic field of the second magnetic device 302. For example, the first magnetic field may be oriented in a positive second direction D2 and the second magnetic field may be oriented in a negative second direction D2 opposite that of the first magnetic field. As such, in a first portion of the body 30 that is immediately adjacent the first magnetic device 301, the magnetic particles 343 may be attracted to and adhere to the inner wall 30a of the body 30 immediately adjacent the first magnet 322A that is on the first side 30t of the body 30. In a second portion of the body 30 that is immediately adjacent the second magnetic device 301, the magnetic particles 343 may be attracted to and adhere to the inner wall 30a of the body 30 immediately adjacent the first magnet 322B that is on the second side 30b of the body 30.

In FIG. 3G, as the magnetic particles 343 traverse along the first direction past the first magnetic device 301 and then past the second magnetic device 302, size of the magnetic particles 343 may increase due to aggregation. As such, size of the magnetic particles 343 in the second portion of the body 30 immediately adjacent the second magnetic device 302 may exceed size of the magnetic particles 343 in the first portion of the body 30 immediately adjacent the first magnetic device 301.

In some embodiments, the magnetic particles 343 flow with the liquid chemical in which they are dispersed through the body 30. In some embodiments, flow rate of the liquid chemical may exceed about 5 milliliters/minute (mL/min), about 300 mL/min, about 500 mL/min, about 1000 mL/min. In some embodiments, the flow rate may be less than about 4000 mL/min, such as being in a range of about 500 mL/min to about 4000 mL/min. Due to the magnetic fields associated with the first and second magnetic devices 301, 302, the magnetic particles 343 may have flow rate through the body 30 that is slower than the flow rate of the liquid chemical.

In some embodiments, an angular offset is present between first orientation of the first magnetic field of the first magnetic device 301 and second orientation of the second magnetic field of the second magnetic device 302. In some embodiments, the angular offset may be in a range of 1° to about 359°, such as about 45°, about 90°, about 30°, about 60°, or another suitable value.

As depicted in FIG. 3G, due to the orientation of the first magnetic field, the magnetic particles 343 may tend to adhere to an area of the inner wall 30a that is relatively small, which can be less than about 180° thereof, such as about 60° or another value. In operation, prior to cleaning the inner wall 30a of the body 30 to remove the magnetic particles 343 adhered thereto, the first and/or second magnetic device 301, 302 may be rotated to change the orientation of the first and/or second magnetic field, which can be beneficial to adhere more magnetic particles 343 to other portions of the inner wall 30a. The rotation can be in response to a selected time interval (e.g., a number of hours, days, weeks, etc.) or in response to detecting that concentration of the magnetic particles 343 in the liquid chemical exceeds a threshold value, such as more than about 5000 parts-per-billion (ppb), more than about 10000 ppb, or another suitable value.

A cleaning operation may be performed on the body 30 to remove the magnetic particles 343 adhered to the inner wall 30a thereof. In some embodiments, the cleaning operation includes at least one of (i) removing the first and second magnetic devices 301, 302, (ii) closing a valve (e.g., the selection device 290) to cut off the body 30 from supplying the liquid chemical to tools, (iii) opening a drain in fluid communication with the body 30, (iv) flowing a first liquid, such as ultrapure water (UPW) through the body 30 for a first selected interval of time, such as about 5 minutes, (v) closing the drain, (vi) filling the body 30 (e.g., partially or fully) with a second liquid, such as H₂SO₄, (vii) soaking the body 30 for a second selected interval of time, such as about 30 minutes, in the second liquid, (viii) draining the second liquid by opening the drain, and (ix) flowing the first liquid through the body 30 for a third selected interval of time, such as about 15 minutes. Following the cleaning operation, the drain may be closed, and the body 30 may be put in fluid communication with the tools by opening the valve. The first and second magnetic devices 301, 302 may then be mounted to the body 30 again, prior to flowing the liquid chemical through the body 30.

Referring to FIG. 2, in some embodiments, during the cleaning operation, opening drains can include, for example, opening the first drain 240, then opening the drain 2522 of the first filter assembly 250, then opening the drain 2522 of the second filter assembly 260, then opening the second drain 280.

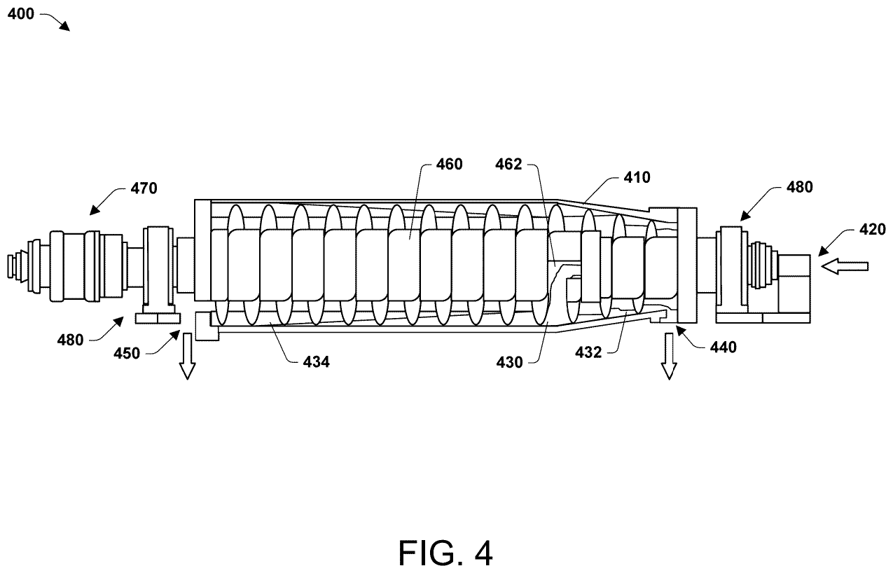

FIG. 4 illustrates a schematic view of a centrifugal particle removal device or “device” 400, in accordance with some embodiments.

The device 400 can be a decanter-type centrifuge, which is operable to separate solid and liquid phases of a contaminated liquid chemical 430, such as magnetic particles 432 and liquid chemical 434 that the magnetic particles 432 are present in. The device can be included in or in fluid communication with the first line 212, the second line 214, or both. The liquid chemical 434 can be the liquid chemical 121 and the magnetic particles 432 can be the magnetic particles 143, 343.

A feed 420 of the device 400 is operable to receive the contaminated liquid chemical 430 into a body or housing 410 of the device 400. The feed 420 can be in fluid communication with an element of one of the transport lines 1311, 1312, 1313, 1321, 1324, 1326, 1336, 1341, 1351, 1352, 1362, 1363, such as one of the first, second, third, fourth, fifth and sixth transport line segments 220, 230, 270, 222, 232, 272 or one of the first, second, third and fourth filter assemblies 250, 260, 252, 262.

A screw conveyor 460 of the device 400 is positioned in the housing 410 and is operable to convey the contaminated liquid chemical 430 into the body 410 via an opening 462 in the screw conveyor 460. The screw conveyor 460 is operable to transport the magnetic particles 432 towards a first discharge outlet 440 while allowing the liquid chemical 434 to move towards a second discharge outlet 450.

The screw conveyor 460 can move at a differential speed relative to the housing 410. A differential 470 of the device 400 is operable to control relative speed difference between the housing 410 and the screw conveyor 460, allowing efficient separation.

The device 400 can include two mountings or “bearing housings” 480 that support rotating components (e.g., the feed 420, the screw conveyor 460, the differential 470, etc.).

The device 400 can be in fluid communication with an element of one of the transport lines 1311, 1312, 1313, 1321, 1324, 1326, 1336, 1341, 1351, 1352, 1362, 1363, such as one of the first, second, third, fourth, fifth and sixth transport line segments 220, 230, 270, 222, 232, 272 or one of the first, second, third and fourth filter assemblies 250, 260, 252, 262. For example, the feed 420 may be in fluid communication with or adjacent to the second filter assembly 260 and the second discharge outlet 450 may be in fluid communication with or adjacent to the third transport line segment 270. In this example, contaminated liquid chemical 430 exiting the second filter assembly 260 can enter the feed 420, the liquid chemical 434 can be separated from the magnetic particles 432 by the screw conveyor 460, and the liquid chemical 434 can be outputted to the third transport line segment 270. Although the device 400 is just described as positioned being between elements of the first line 212 or the second line 214, the device can be positioned between an inlet or outlet of one of the transport lines 1311, 1312, 1313, 1321, 1324, 1326, 1336, 1341, 1351, 1352, 1362, 1363 and an outlet or inlet of one of the intake assembly 131, the storage tanks 132, 133, the retrieval assembly 134, the supply assembly 135 and the feedback assembly 136.

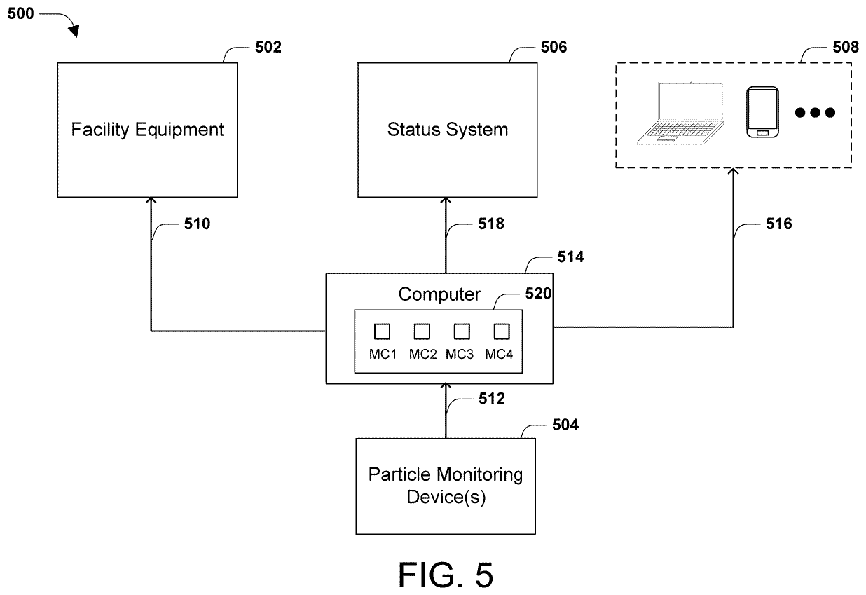

FIG. 5 illustrates a schematic view of a particle monitoring system or “system” 500, in accordance with some embodiments. The particle monitoring system 500 comprises at least one of a set of particle monitoring devices 504, facility equipment 502 of a facility, a computer 514, a status system 506, or one or more client devices 508. The set of particle monitoring devices 504 comprises particle monitoring devices distributed at various locations of the facility. The particle monitoring devices are used to determine measurements associated with devices and/or other equipment in the facility, such as the intake assembly 131, the retrieval assembly 134, the supply assembly 135, and the feedback assembly 136 described with reference to FIG. 1B. In some embodiments, the particle monitoring devices are used to determine measurements associated with the transport lines 1311, 1312, 1313, 1321, 1324, 1326, 1336, 1341, 1351, 1352, 1362, 1363 described with reference to FIG. 1B.

In some embodiments, the set of particle monitoring devices 504 transmit a set of monitoring signals 512 to the computer 514. In some embodiments, each signal of the set of monitoring signals 512 is transmitted by a monitoring device (e.g., the supply assembly 135), of the set of particle monitoring devices 504, in a liquid chemical supply system of the facility.

In some embodiments, the set of monitoring signals 512 comprises a first monitoring signal from the supply assembly 135. In some embodiments, the supply assembly 135 comprises a wireless communication module that transmits the first monitoring signal to the computer 514 wirelessly. In some embodiments, the supply assembly 135 transmits the first monitoring signal to the computer 514 over a wired connection between the supply assembly 135 and the computer 514. In some embodiments, the first monitoring signal is indicative of the level of particles (e.g., particle count) associated with the liquid chemical 121 sampled by the supply assembly 135.

In some embodiments, the set of monitoring signals 512 comprises a second monitoring signal from the supply assembly 135. In some embodiments, the second monitoring signal is indicative of the level of particles (e.g., particle count) associated with the liquid chemical 121 sampled by the supply assembly 135. The first monitoring signal may be indicative of a first level of particles associated with a first time, and the second monitoring signal may be indicative of a second level of particles associated with a second time. The first time and the second time may be positioned between two successive cleaning operations associated with the first line 212 or the second line 214.

In some embodiments, the computer 514 controls a display panel 520 comprising a set of status indicators associated with apparatuses (e.g., first, second, third and fourth magnetic devices indicated by “MC1,” “MC2,” “MC3,” and “MC4,” respectively) of the liquid chemical supply system in the facility. In some embodiments, an indicator of the set of status indicators comprises a light, such as an indicator light, that indicates whether a corresponding apparatus is associated with a particle level, wherein the light being in a first state indicates that the corresponding apparatus is associated with the particle level exceeding a threshold value and/or the light being in a second state indicates that the corresponding apparatus is not associated with the particle level exceeding the threshold value. In some embodiments, the display panel 520 comprises a display configured to display an alert indicative of one or more detected particle monitoring statuses of one or more apparatuses. In some embodiments, the first state corresponds to a first color emitted by the light, such as red or other color, and the second state corresponds to a second color emitted by the light, such as green or other color. The set of status indicators comprises at least one of a first indicator “MC1” associated with a first apparatus (e.g., the first line 212), a second indicator “MC2” associated with a second apparatus (e.g., the second line 214), a third indicator “MC3” associated with a third apparatus (e.g., another line similar to the first and second transport lines 212, 214), a fourth indicator “MC4” associated with a fourth apparatus (e.g., yet another line similar to the first and second transport lines 212, 214), or other indicator.

In some embodiments, the computer 514 provides one or more first signals 510 to the facility equipment 502. In some embodiments, the one or more first signals 510 are used to control at least some of the facility equipment 502, such as one, some or all liquid chemical supply systems of the facility and/or other equipment of the facility. In some embodiments, the one or more first signals 510 are generated using a signal generator of the computer 514. The one or more first signals 510 can be indicative of particle level of liquid chemical in the liquid chemical supply system(s). In some embodiments, the computer 514 transmits the one or more first signals 510 to the facility equipment 502 wirelessly, such as using a wireless communication device of the computer 514. In some embodiments, the computer 514 transmits the one or more first signals 510 to the facility equipment 502 over a physical connection between the computer 514 and the facility equipment 502. In some embodiments, the computer 514 transmits the one or more first signals 510 to a controller that controls one or more valves, drains, or selection devices of the liquid chemical supply system. In some embodiments, the controller controls removal or attachment of one or more magnetic devices (e.g., the magnetic device 300) to one or more respective transport lines or filter assemblies (e.g., the first, second, third, fourth, fifth and sixth transport line segments 220, 230, 270, 222, 232, 272, the first, second, third and fourth filter assemblies 250, 260, 252, 262, etc.).

In some embodiments, the computer 514 transmits a second signal 518 to the status system 506. The second signal 518 is generated using the signal generator of the computer 514. In some embodiments, the second signal 518 is indicative of at least one of (i) the set of particle monitoring statuses, (ii) the list of apparatuses that are determined to have particle level exceeding a selected threshold value, or (iii) other information. In some embodiments, the computer 514 transmits the second signal 518 to the status system 506 wirelessly, such as using the wireless communication device of the computer 514. In some embodiments, the computer 514 transmits the second signal 518 to the status system 506 over a physical connection between the computer 514 and the status system 506. In some embodiments, the status system 506 triggers an alarm function based upon the second signal 518. In some embodiments, the status system 506 triggers the alarm function based upon the second signal 518 indicating that the apparatus is associated with a particle level exceeding the selected threshold value. In some embodiments, in response to triggering the alarm function, an alarm message is displayed via a display of the status system 506. The alarm message comprises at least one of an indication that the apparatus is associated with the particle level exceeding the selected threshold value, an indication of lead time to perform preventative maintenance, an indication comprising an instruction for the liquid chemical supply system to cease operating (until the particle level is sufficiently low, for example), or other indication. In some embodiments, an alarm sound is output via a speaker connected to the status system 506 in response to triggering the alarm function.

In some embodiments, the computer 514 transmits a third signal 516 to one or more client devices 508. The one or more client devices 508 comprise at least one of a phone, a smartphone, a mobile phone, a landline, a laptop, a desktop computer, hardware, or other type of client device. The third signal 516 is generated using the signal generator of the computer 514. In some embodiments, the third signal 516 is indicative of at least one of (i) the set of particle monitoring statuses, (ii) the list of apparatuses that are determined to be associated with the particle level that exceeds the selected threshold value, or (iii) other information. In some embodiments, the computer 514 transmits the third signal 516 to a client device of the one or more client devices 508 wirelessly, such as using the wireless communication device of the computer 514. In some embodiments, the computer 514 transmits the third signal 516 to a client device of the one or more client devices 508 over a physical connection between the computer 514 and the client device. In some embodiments, the third signal 516 comprises a message, such as at least one of an email, a text message, etc., transmitted in response to detecting one or more particle levels that exceed the selected threshold value. In some embodiments, in response to detecting a particle value exceeding the selected threshold value associated with an apparatus, a telephonic call is made to a client device, such as a landline or a mobile phone, of the one or more client devices 508, such as using a dialer of the computer 514.

In some embodiments, the set of monitoring signals 512 are used as feedback based upon which operation of the facility equipment 502 is controlled by the computer 514. In some embodiments, the computer 514 controls operation of the facility equipment 502 based upon measurements provided by the set of monitoring signals 512. In some embodiments, operation of the facility equipment 502 is controlled using the one or more first signals 510. In some embodiments, a signal of the one or more first signals 510 is indicative of one or more instructions.

In some embodiments, the system 100 of the facility equipment 502 at least one of begins a cleaning operation of a magnetic device, slows flow rate of the liquid chemical, halts supply of liquid chemical to tools, or performs another operation in response to receiving a signal (of the one or more first signals 510) indicating that the particle level exceeds the selected threshold value. In some embodiments, the one or more first signals 510 comprise a signal transmitted to a machine, such as the system 100. In some embodiments, the signal instructs the machine to engage the second line 214 while the first line 212 is undergoing preventative maintenance (e.g., the cleaning operation described with reference to FIGS. 2-3G). In some embodiments, the signal allocates one or more resources (e.g., manpower, a robot, one or more tools, the replacement component, etc.) to the first line 212 to be used for cleaning the first line 212.

In some embodiments, in response to determining that first line 212 is not associated with a cleaning operation, the first line 212 is used to supply liquid chemical to the tool(s), so as to perform an etching process or other suitable process on the first semiconductor wafer 150. In some embodiments, in response to determining that the first line 212 is associated with the cleaning operation, the computer 514 instructs the first line 212 to not deliver the liquid chemical (until the cleaning operation is completed, for example). During the system 100 not delivering the liquid chemical via the first line 212, the system 100 may deliver the liquid chemical via another line, such as the second line 214.

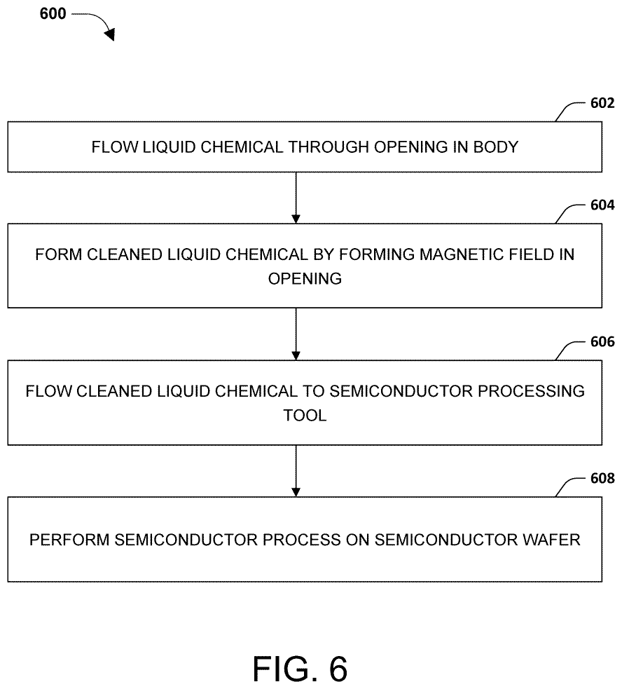

FIG. 6 is a flow diagram illustrating a method 600 of operating a liquid chemical supply system, in accordance with some embodiments.

The method 600 is illustrated in FIG. 6 in accordance with some embodiments.

At 602, the method 600 includes flowing a liquid chemical through an opening defined in a body. The liquid chemical has magnetic particles dispersed therein.

At 604, the method 600 includes forming cleaned liquid chemical, including forming a magnetic field in the opening by a magnetic device mounted to the body. In some embodiments, forming the magnetic field in 604 includes forming the magnetic field by the magnetic device that includes a Halbach array having two turns. In some embodiments, forming the magnetic field in 604 includes forming the magnetic field by the magnetic device that includes the Halbach array having at least eight magnets. In some embodiments, forming the magnetic field in 604 includes forming the magnetic field by the magnetic device that includes the Halbach array having at least eight magnets that are embedded in a housing. In some embodiments, forming the magnetic field in 604 includes forming the magnetic field by the magnetic device that is in direct contact with the body. In some embodiments, forming the magnetic field in 604 includes forming the magnetic field by the magnetic device that is in direct contact with the body. Ratio of surface area of the body in a region of the body overlapped by the magnetic device that is in direct contact with the body exceeds about 50%.

At 606, the method 600 includes flowing the cleaned liquid chemical to a semiconductor processing tool.

At 608, the method 600 includes performing a semiconductor process on a semiconductor wafer by the semiconductor processing tool by the cleaned liquid chemical.

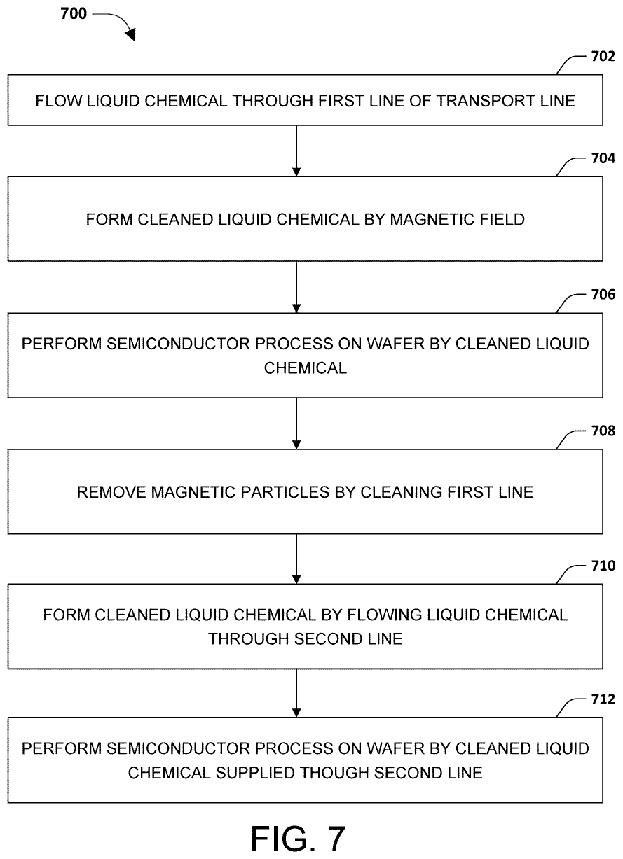

FIG. 7 is a flow diagram illustrating a method 700, in accordance with some embodiments.

The method 700 is illustrated in FIG. 7 in accordance with some embodiments.

At 702, the method 700 includes flowing a liquid chemical through a first line of a transport line of a liquid chemical supply system, the liquid chemical having magnetic particles dispersed therein.

At 704, the method 700 includes forming cleaned liquid chemical, including adhering the magnetic particles to an inner wall of the first line by forming a magnetic field by a first magnetic device mounted to the first line.

In some embodiments, forming the magnetic field by the first magnetic device in 704 includes forming the magnetic field by the first magnetic device mounted to a transport line segment of the first line. In some embodiments, forming the magnetic field by the first magnetic device in 704 includes forming the magnetic field by the first magnetic device mounted to a filter assembly of the first line.

In some embodiments, adhering the magnetic particles to the inner wall of the first line in 704 includes adhering the magnetic particles to a first portion of the inner wall, the first portion being associated with a first orientation of the magnetic field. In some embodiments, adhering the magnetic particles to the inner wall in 704 includes, after adhering the magnetic particles to the first portion, adhering the magnetic particles to a second portion of the inner wall by generating a second orientation of the magnetic field by rotating the first magnetic device.

At 706, the method 700 includes performing a semiconductor process on a wafer by the cleaned liquid chemical supplied through the first line.

At 708, the method 700 includes, following forming the cleaned liquid chemical, removing the magnetic particles from the inner wall by cleaning the first line.

In some embodiments, cleaning the first line in 708 includes: opening a first drain adjacent to a first filter assembly; following opening the first drain, opening a second drain of the first filter assembly; following opening the drain, opening a third drain of a second filter assembly adjacent the first filter assembly; and following opening the drain of the second filter assembly, opening a fourth drain adjacent the second filter assembly.

In some embodiments, cleaning the first line in 708 includes cleaning the first line in response to a selected interval of time. In some embodiments, cleaning the first line in 708 includes cleaning the first line in response to concentration of the magnetic particles in the cleaned liquid chemical exceeding a threshold value.

In some embodiments, cleaning the first line in 708 includes: flowing first ultrapure water through the first line; after flowing the first ultrapure water, flowing an acid through the first line; and after flowing the acid, flowing second ultrapure water through the first line.

At 710, the method 700 includes, during cleaning the first line, forming the cleaned liquid chemical by flowing the liquid chemical through a second line of the transport line, the second line having a second magnetic device mounted thereto.

At 712, the method 700 includes performing the semiconductor process on the wafer by the cleaned liquid chemical supplied through the second line.

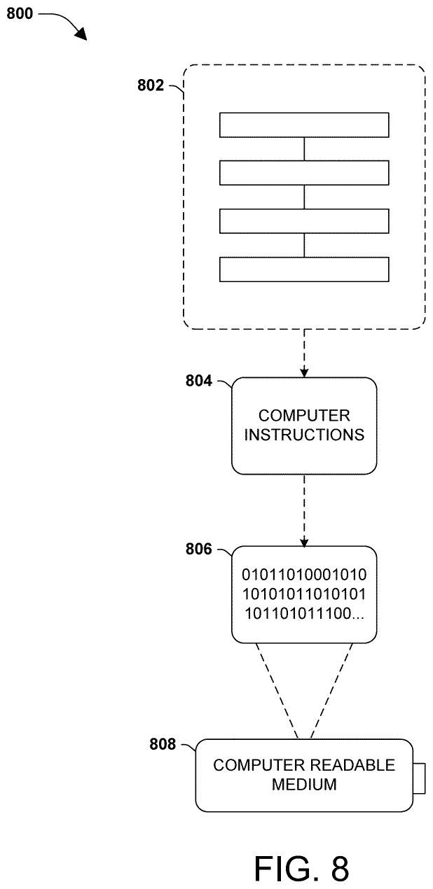

FIG. 8 illustrates an example computer-readable medium wherein processor-executable instructions configured to embody one or more of the provisions set forth herein may be comprised, according to some embodiments.

One or more embodiments involve a computer-readable medium comprising processor-executable instructions configured to implement one or more of the techniques presented herein. An exemplary computer-readable medium is illustrated in FIG. 8, wherein the embodiment 800 comprises a computer-readable medium 808 (e.g., a CD-R, DVD-R, flash drive, a platter of a hard disk drive, etc.), on which is encoded computer-readable data 806. This computer-readable data 806 in turn comprises a set of processor-executable computer instructions 804 configured to implement one or more of the principles set forth herein when executed by a processor. In some embodiments 800, the processor-executable computer instructions 804 are configured to implement a method 802, such as at least some of the aforementioned method(s) when executed by a processor. In some embodiments, the processor-executable computer instructions 804 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a method is provided. The method includes: flowing a liquid chemical through an opening defined in a body, the liquid chemical having magnetic particles dispersed therein; forming cleaned liquid chemical, including forming a magnetic field in the opening by a magnetic device mounted to the body; flowing the cleaned liquid chemical to a semiconductor processing tool; and performing a semiconductor process on a semiconductor wafer by the semiconductor processing tool by the cleaned liquid chemical.

In some embodiments, a method is provided. The method includes: flowing a liquid chemical through a first line of a transport line of a liquid chemical supply system, the liquid chemical having magnetic particles dispersed therein; forming cleaned liquid chemical, including adhering the magnetic particles to an inner wall of the first line by forming a magnetic field by a first magnetic device mounted to the first line; performing a semiconductor process on a wafer by the cleaned liquid chemical supplied through the first line; following forming the cleaned liquid chemical, removing the magnetic particles from the inner wall by cleaning the first line; during cleaning the first line, forming the cleaned liquid chemical by flowing the liquid chemical through a second line of the transport line, the second line having a second magnetic device mounted thereto; and performing the semiconductor process on the wafer by the cleaned liquid chemical supplied through the second line.

In some embodiments, a system is provided. The system includes: a storage tank operable to store a liquid chemical; a plurality of apparatuses in fluid communication with the storage tank and a semiconductor processing tool; a transport line having an outlet in fluid communication with one of the plurality of apparatuses. The transport line includes: a first transport line segment having a first opening defined therein; and a first filter assembly in fluid communication with the first transport line segment, the first filter assembly having a second opening defined therein. The system includes: a first magnetic device mounted to the first transport line segment, the first magnetic device generating a first magnetic field in the first opening; and a second magnetic device mounted to the first filter assembly, the second magnetic device generating a second magnetic field in the second opening.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method, comprising:
flowing a liquid chemical through an opening defined in a body, the liquid chemical having magnetic particles dispersed therein;
forming cleaned liquid chemical, including forming a magnetic field in the opening by a magnetic device mounted to the body;
flowing the cleaned liquid chemical to a semiconductor processing tool; and
performing a semiconductor process on a semiconductor wafer by the semiconductor processing tool by the cleaned liquid chemical.

2. The method of claim 1, wherein forming the magnetic field includes:
forming the magnetic field by the magnetic device that includes a Halbach array having two turns.

3. The method of claim 2, wherein forming the magnetic field includes:
forming the magnetic field by the magnetic device that includes the Halbach array having at least eight magnets.

4. The method of claim 2, wherein forming the magnetic field includes:
forming the magnetic field by the magnetic device that includes the Halbach array having at least eight magnets that are embedded in a housing.

5. The method of claim 1, wherein forming the magnetic field includes:
forming the magnetic field by the magnetic device that is in direct contact with the body.

6. The method of claim 5, wherein forming the magnetic field includes:
forming the magnetic field by the magnetic device that is in direct contact with the body, wherein ratio of surface area of the body in a region of the body overlapped by the magnetic device that is in direct contact with the body exceeds about 50%.

7. A method, comprising:
flowing a liquid chemical through a first line of a transport line of a liquid chemical supply system, the liquid chemical having magnetic particles dispersed therein;
forming cleaned liquid chemical, including adhering the magnetic particles to an inner wall of the first line by forming a magnetic field by a first magnetic device mounted to the first line;
performing a semiconductor process on a wafer by the cleaned liquid chemical supplied through the first line;
following forming the cleaned liquid chemical, removing the magnetic particles from the inner wall by cleaning the first line;
during cleaning the first line, forming the cleaned liquid chemical by flowing the liquid chemical through a second line of the transport line, the second line having a second magnetic device mounted thereto; and
performing the semiconductor process on the wafer by the cleaned liquid chemical supplied through the second line.

8. The method of claim 7, wherein forming the magnetic field by the first magnetic device includes:
forming the magnetic field by the first magnetic device mounted to a transport line segment of the first line.

9. The method of claim 7, wherein forming the magnetic field by the first magnetic device includes:
forming the magnetic field by the first magnetic device mounted to a filter assembly of the first line.

10. The method of claim 7, wherein cleaning the first line includes:
opening a first drain adjacent to a first filter assembly;
following opening the first drain, opening a second drain of the first filter assembly;
following opening the drain, opening a third drain of a second filter assembly adjacent the first filter assembly; and
following opening the drain of the second filter assembly, opening a fourth drain adjacent the second filter assembly.

11. The method of claim 7, wherein cleaning the first line includes:
cleaning the first line in response to a selected interval of time.

12. The method of claim 7, wherein cleaning the first line includes:
cleaning the first line in response to concentration of the magnetic particles in the cleaned liquid chemical exceeding a threshold value.

13. The method of claim 7, wherein adhering the magnetic particles to the inner wall of the first line includes:
adhering the magnetic particles to a first portion of the inner wall, the first portion being associated with a first orientation of the magnetic field.

14. The method of claim 13, wherein adhering the magnetic particles to the inner wall includes:
after adhering the magnetic particles to the first portion, adhering the magnetic particles to a second portion of the inner wall by generating a second orientation of the magnetic field by rotating the first magnetic device.

15. The method of claim 7, wherein cleaning the first line includes:
flowing first ultrapure water through the first line;
after flowing the first ultrapure water, flowing an acid through the first line; and
after flowing the acid, flowing second ultrapure water through the first line.

16. A system, comprising:
a storage tank operable to store a liquid chemical;
a plurality of apparatuses in fluid communication with the storage tank and a semiconductor processing tool;
a transport line having an outlet in fluid communication with one of the plurality of apparatuses, the transport line including:
a first transport line segment having a first opening defined therein; and
a first filter assembly in fluid communication with the first transport line segment, the first filter assembly having a second opening defined therein;
a first magnetic device mounted to the first transport line segment, the first magnetic device generating a first magnetic field in the first opening; and
a second magnetic device mounted to the first filter assembly, the second magnetic device generating a second magnetic field in the second opening.

17. The system of claim 16, wherein the first magnetic device includes at least eight magnets that are arranged in an array that wraps around the first opening.

18. The system of claim 16, further comprising:
a third magnetic device mounted to the first transport line segment adjacent the first magnetic device, the third magnetic device generating a third magnetic field in the first opening, the third magnetic field having third orientation that is different than a first orientation of the first magnetic field.

19. The system of claim 18, wherein the third magnetic device includes a different arrangement of magnets than that of the first magnetic device.

20. The system of claim 16, wherein the first transport line includes:
a second transport line segment between the first transport line segment and the first filter assembly;
a second filter assembly adjacent the first filter assembly;
a third transport line segment adjacent the second filter assembly;
a first drain between the second transport line segment and the first filter assembly; and
a second drain adjacent the third transport line segment.
